(19) United States
(12) Patent Application Publication
(10) Pub. No.: US 2025/0133930 A1
(43) Pub. Date: Apr. 24, 2025

(54) LIGHT EMITTING DEVICE, DISPLAY DEVICE, PHOTOELECTRIC CONVERSION DEVICE, ELECTRONIC APPARATUS, ILLUMINATION DEVICE, AND MOVING BODY

(71) Applicant: CANON KABUSHIKI KAISHA, Tokyo (JP)

(72) Inventors: TETSUO TAKAHASHI, Kanagawa (JP); KOJI ISHIZUYA, Kanagawa (JP); TAKAYUKI ITO, Kanagawa (JP); YOJIRO MATSUDA, Kanagawa (JP); EISUKE GOMMORI, Kanagawa (JP); SHOMA HINATA, Kanagawa (JP); AKIRA OKITA, Kanagawa (JP)

(21) Appl. No.: 18/989,731

(22) Filed: Dec. 20, 2024

Related U.S. Application Data
(63) Continuation of application No. PCT/JP2023/019664, filed on May 26, 2023.

(30) Foreign Application Priority Data
Jul. 21, 2022 (JP) 2022-116573
Jan. 18, 2023 (JP) 2023-006066

(51) Int. Cl. H10K 59/80

(52) U.S. Cl. CPC H10K 59/80518; H10K 59/80515; H10K 59/80521; H10K 59/878

(57) ABSTRACT

A light emitting device is provided. The device includes an insulating layer arranged on a main surface of a substrate, lower electrodes arranged on the insulating layer, an organic layer arranged to cover the lower electrodes, an upper electrode arranged to cover the organic layer, and a supply electrode configured to supply a potential to the upper electrode. The organic layer includes function layers each including a light emitting layer, and a charge generation layer arranged between the function layers, the upper electrode includes a contact portion that is in contact with the supply electrode, the insulating layer includes a trench between the contact portion and each of the lower electrodes, and a thickness of the charge generation layer in the trench is thinner than the thickness of the charge generation layer on the lower electrodes.

### CROSS-REFERENCE TO RELATED APPLICATIONS

This application is a Continuation of International Patent Application No. PCT/JP2023/019664, filed May 26, 2023, which claims the benefit of Japanese Patent Applications No. 2022-116573 filed Jul. 21, 2022, and Japanese Patent Applications No. 2023-006066 filed Jan. 18, 2023, all of which are hereby incorporated by reference herein in their entirety.

### BACKGROUND OF THE INVENTION

### Field of the Invention

The present invention relates to a light emitting device, a display device, a photoelectric conversion device, an electronic apparatus, an illumination device, and a moving body.

### Background Art

Interest in a light emitting device using a self-light emitting element such as an organic electroluminescence (EL) element has increased. For color display in a light emitting device, there is known a method (white/CF method) using color filters and a light emitting element that emits white light. PTL 1 discloses a tandem-type organic EL display in which a plurality of light emitting layers are stacked, and a charge generation layer is arranged between the light emitting layers, in addition to the white/CF method.

### CITATION LIST

### Patent Literature

PTL 1: US-2018-0102499

By the plurality of light emitting layers and the charge generation layer arranged between the light emitting layers, the efficiency of the light emitting device can be increased. However, since the charge generation layer is highly conductive, the display quality of an image may lower due to a leakage current via the charge generation layer.

It is an object of the present invention to provide a technique advantageous in suppressing lowering of the display quality of a light emitting device.

### SUMMARY OF THE INVENTION

According to some embodiments, a light emitting device including: an insulating layer arranged on a main surface of a substrate; a plurality of lower electrodes arranged on the insulating layer; an organic layer arranged to cover the plurality of lower electrodes; an upper electrode arranged to cover the organic layer; and a supply electrode configured to supply an electric potential to the upper electrode, wherein the organic layer includes a plurality of function layers each including a light emitting layer, and a charge generation layer arranged between the plurality of function layers, the upper electrode includes a contact portion that is in contact with the supply electrode, in orthogonal projection to the main surface, the insulating layer includes a trench between the contact portion and each of the plurality of lower electrodes, and a thickness of the charge generation layer in the trench is thinner than the thickness of the charge generation layer on the plurality of lower electrodes, is provided.

According to some other embodiments, a light emitting device including: an insulating layer arranged on a main surface of a substrate; a plurality of lower electrodes arranged on the insulating layer; an organic layer arranged to cover the plurality of lower electrodes; an upper electrode arranged to cover the organic layer; and a supply electrode configured to supply an electric potential to the upper electrode, wherein the organic layer includes a plurality of function layers each including a light emitting layer, and a charge generation layer arranged between the plurality of function layers, the upper electrode includes a contact portion that is in contact with the supply electrode, and an electric field application electrode configured to apply an electric field to the charge generation layer is arranged between the insulating layer and the organic layer and, in orthogonal projection to the main surface, between the contact portion and each of the plurality of lower electrodes, is provided.

According to still other embodiments, a light emitting device including: a first insulating layer arranged on a main surface of a substrate; a plurality of lower electrodes arranged on the first insulating layer; a second insulating layer arranged on the first insulating layer and between the plurality of lower electrodes; an organic layer arranged to cover the plurality of lower electrodes and the second insulating layer; an upper electrode arranged to cover the organic layer; and a supply electrode configured to supply an electric potential to the upper electrode, wherein the organic layer includes a plurality of function layers each including a light emitting layer, and a charge generation layer arranged between the plurality of function layers, the upper electrode includes a contact portion that is in contact with the supply electrode, on a surface of the second insulating layer facing the organic layer, a tilting portion having a tilt with respect to the main surface is arranged between the contact portion and each of the plurality of lower electrodes in orthogonal projection to the main surface, a conductive layer is further arranged between the main surface and the tilting portion to overlap the tilting portion in orthogonal projection to the main surface, and an electric potential of the conductive layer is lower than that of the plurality of lower electrodes in a case where the plurality of lower electrodes serve as an anode and the upper electrode serves as a cathode, and higher than that of the plurality of lower electrodes in a case where the plurality of lower electrodes serve as a cathode and the upper electrode serves as an anode, is provided.

Further features of the present invention will become apparent from the following description of exemplary embodiments with reference to the attached drawings.

### BRIEF DESCRIPTION OF THE DRAWINGS

The accompanying drawings, which are incorporated in and constitute a part of the specification, illustrate embodiments of the invention and, together with the description, serve to explain principles of the invention.

FIG. 1 is a plan view showing an example of the configuration of a light emitting device according to the embodiment.

FIG. 2 is a plan view showing an example of the configuration of the light emitting device shown in FIG. 1.

FIG. 3 is a sectional view showing an example of the configuration of the light emitting device shown in FIG. 1.

FIG. 4 is a sectional view showing an example of the configuration of the light emitting device shown in FIG. 1.

FIG. 5A is a sectional view showing a method of manufacturing the light emitting device shown in FIG. 1.

FIG. 5B is a sectional view showing a method of manufacturing the light emitting device shown in FIG. 1.

FIG. 5C is a sectional view showing a method of manufacturing the light emitting device shown in FIG. 1.

FIG. 6A is a view showing a method of manufacturing the light emitting device shown in FIG. 1.

FIG. 6B is a view showing a method of manufacturing the light emitting device shown in FIG. 1.

FIG. 7 is a plan view showing an example of the configuration of the light emitting device shown in FIG. 1.

FIG. 8 is a plan view showing an example of the configuration of the light emitting device shown in FIG. 1.

FIG. 9A is a plan view showing an example of the configuration of the light emitting device shown in FIG. 1.

FIG. 9B is a plan view showing an example of the configuration of the light emitting device shown in FIG. 1.

FIG. 9C is a plan view showing an example of the configuration of the light emitting device shown in FIG. 1.

FIG. 10 is a plan view showing an example of the configuration of the light emitting device shown in FIG. 1.

FIG. 11 is a sectional view showing an example of the configuration of the light emitting device shown in FIG. 1.

FIG. 12 is a sectional view showing an example of the configuration of the light emitting device shown in FIG. 1.

FIG. 13 is a plan view showing an example of the configuration of the light emitting device shown in FIG. 1.

FIG. 14 is a sectional view showing an example of the configuration of the light emitting device shown in FIG. 1.

FIG. 15 is a sectional view showing an example of the configuration of the light emitting device shown in FIG. 1.

FIG. 16 is a sectional view showing an example of the configuration of the light emitting device shown in FIG. 1.

FIG. 17 is a sectional view showing an example of the configuration of the light emitting device shown in FIG. 1.

FIG. 18 is a plan view showing an example of the configuration of the light emitting device shown in FIG. 1.

FIG. 19 is a sectional view showing an example of the configuration of a light emitting device according to a comparative example.

FIG. 20 is a plan view showing an example of the configuration of a light emitting device according to a comparative example.

FIG. 21 is a view for explaining a deposition simulation when forming the light emitting device shown in FIG. 1.

FIG. 22 is a view for explaining a deposition simulation result when forming the light emitting device shown in FIG. 1.

FIG. 23 is a sectional view showing an example of the configuration of the light emitting device shown in FIG. 1.

FIG. 24 is a plan view showing an example of the configuration of the light emitting device shown in FIG. 1.

FIG. 25 is a view showing an example of a display device using the light emitting device according to the embodiment.

FIG. 26 is a view showing an example of a photoelectric conversion device using the light emitting device according to the embodiment.

FIG. 27 is a view showing an example of an electronic apparatus using the light emitting device according to the embodiment.

FIG. 28A is a view showing an example of a display device using the light emitting device according to the embodiment.

FIG. 28B is a view showing an example of a display device using the light emitting device according to the embodiment.

FIG. 29 is a view showing an example of an illumination device using the light emitting device according to the embodiment.

FIG. 30 is a view showing an example of a moving body using the light emitting device according to the embodiment.

FIG. 31A is a view showing an example of a wearable device using the light emitting device according to the embodiment.

FIG. 31B is a view showing an example of a wearable device using the light emitting device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

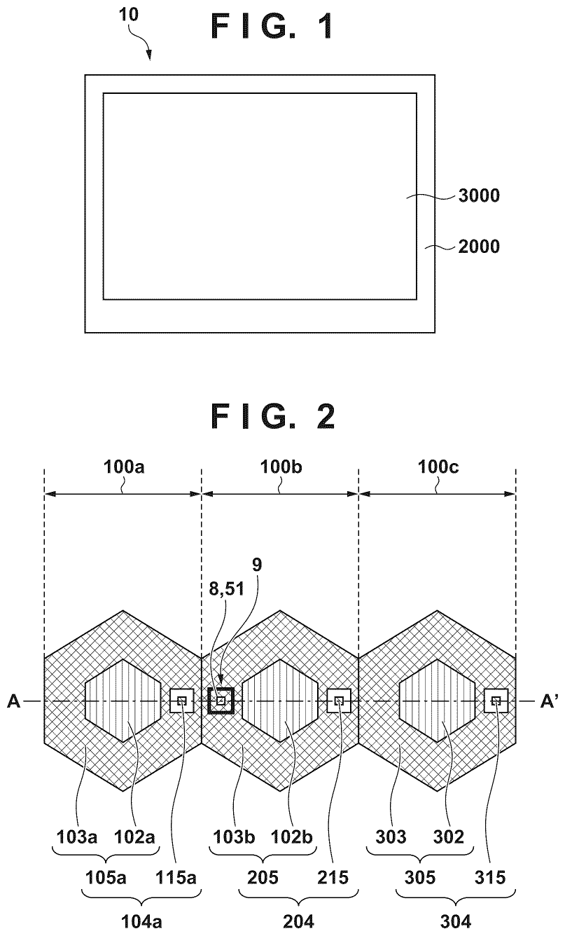

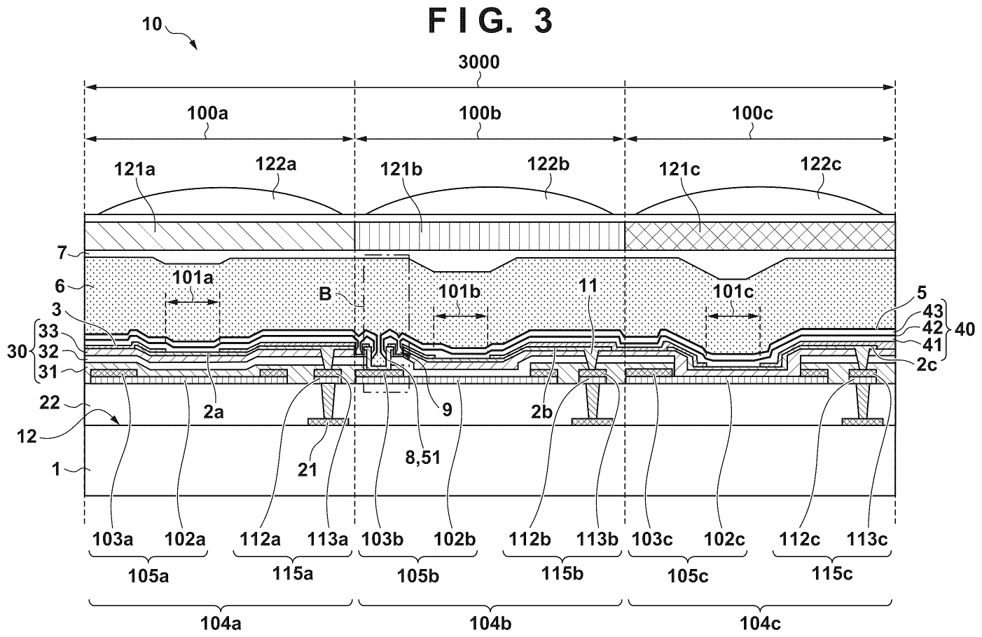

A display device according to an embodiment of the present disclosure will be described with reference to FIGS. 1 to 24. FIG. 1 is a plan view showing an example of the configuration of a light emitting device 10 according to the embodiment. FIG. 2 is an enlarged view of part of a display region 3000 of the light emitting device 10 shown in FIG. 1, and is a plan view obtained by extracting three organic light emitting elements 100 included in the display region 3000. FIG. 3 is a sectional view taken along a line A-A′ in the plan view shown in FIG. 2.

As shown in FIG. 1, the light emitting device 10 includes the display region 3000 and an outer peripheral region 2000 provided on the periphery of the display region 3000. The display region 3000 is a region where the organic light emitting elements 100 (to also be referred to as pixels or sub-pixels) each for emitting light are arrayed, and may be used to display an image, characters, and the like or may be used as a light source used for illumination as in an application example to be described later. In the outer peripheral region 2000, a driving circuit for performing appropriate display in the display region 3000 and the like can be arranged. In the configuration shown in FIG. 1, the outer peripheral region 2000 is arranged to surround the display region 3000 but is not limited to this. For example, the outer peripheral region 2000 may be provided along only one side of the display region 3000 or provided along two or three sides of the display region 3000.

The light emitting device 10 will be described in more detail with reference to FIGS. 2 and 3. In the display region 3000 of the light emitting device 10, the plurality of organic light emitting elements 100 are arranged. When a specific one of the plurality of organic light emitting elements 100 is indicated, a suffix is added after a reference numeral like an organic light emitting element 100″a″. When the organic light emitting elements 100 need not particularly be discriminated, they will be referred to as the “organic light emitting element 100”. The same applies to other constituent elements.

The light emitting device 10 can include an insulating layer 30 arranged on a main surface 12 of a substrate 1, a plurality of lower electrodes 2 arranged on the insulating layer 30, an organic layer 40 arranged to cover the plurality of lower electrodes 2, an upper electrode 5 arranged to cover the organic layer 40, and a supply electrode 8 that supplies an electric potential to the upper electrode 5. Also, a reflective layer 102 may be arranged between the main surface 12 of the substrate 1 and the insulating layer 30. The positions of the organic light emitting elements 100 can be decided by the lower electrodes 2 arranged electrically independent of each other. On the other hand, the organic layer 40 and the upper electrode 5 can be shared by the plurality of organic light emitting elements 100. One organic layer 40 and one upper electrode 5 may be arranged on the entire display region 3000. That is, the organic layer 40 may be formed integrally on the entire display region 3000 of the light emitting device 10 in which an image or the like is displayed. Similarly, the upper electrode 5 may be formed integrally on the entire display region 3000 of the light emitting device 10 in which an image or the like is displayed. Each organic light emitting element 100 can be a self-light emitting element such as an organic electroluminescence (EL) element.

For the substrate 1, a material that can support the respective constituent elements such as the lower electrodes 2, the organic layer 40, and the upper electrode 5 is used. As the substrate 1, for example, glass, plastic, silicon, or the like can be applied. On the substrate 1, a switching element (not shown) such as a transistor, a conductor 11, an interlayer insulating layer 22, and the like can be formed.

The lower electrode 2 of the organic light emitting element 100 may transmit light emitted from the light emitting layer of the organic layer 40. For the lower electrode 2, a transparent conductive oxide such as indium tin oxide (ITO) or zinc indium oxide (IZO) can be used. For the lower electrode 2, a thin film of a metal such as aluminum (Al), silver (Ag), or platinum (Pt), or an alloy thereof may be used. The film thickness of the lower electrode 2 may be different between an organic light emitting element 100a, an organic light emitting element 100b, and an organic light emitting element 100c. The organic light emitting element 100a, the organic light emitting element 100b, and the organic light emitting element 100c may have different optical resonator structures. The optical resonator structure may be formed by providing a light reflection layer under each lower electrode and providing a different optical distance.

The organic layer 40 is arranged on the lower electrodes 2 of the organic light emitting elements 100. In this embodiment, the organic layer 40 is of a so-called tandem type including a plurality of function layers 41 and 43 each including a light emitting layer, and a charge generation layer 42 arranged between the function layer 41 and the function layer 43. The number of function layers is not limited to two, and three or more function layers each including a light emitting layer may be stacked. If three or more function layers are stacked, the charge generation layer may be arranged between the function layers. That is, the charge generation layer may be arranged between a light emitting layer and another light emitting layer. This is because the charge generation layer 42 is arranged between the function layer 41 including a light emitting layer and the function layer 43 including another light emitting layer.

Each of the function layers 41 and 43 is a layer including at least a light emitting layer, and may be formed by a plurality of layers. Examples of layers other than the light emitting layer are a hole injection layer, a hole transport layer, an electron blocking layer, a light emitting layer, a hole blocking layer, an electron transport layer, and an electron injection layer. In each of the function layers 41 and 43, holes injected from an anode and electrons injected from a cathode recombine in the light emitting layer, and light is emitted from the light emitting layer. The configuration of the light emitting layer may be a single layer structure or a multilayer structure. The light emitting layers can contain a red light emitting material, a green light emitting material, and a blue light emitting material, and the light emission colors can be mixed to obtain white light. In addition, the light emitting layers may contain light emitting materials having a complimentary color relationship, such as a blue light emitting material and a yellow light emitting material. For example, the light emitting layer arranged in the function layer 41 may contain a red light emitting material and a green light emitting material, and the light emitting layer arranged in the function layer 43 may contain a blue light emitting material.

The charge generation layer 42 is a layer that contains an electron donating material and an electron accepting material and generates charges. The electron donating material and the electron accepting material are a material that gives electrons and a material that accepts the electrons, respectively. Since positive and negative charges are generated in the charge generation layer 42, the positive or negative charge can be supplied to the function layers 41 and 43 arranged on the upper and lower sides of the charge generation layer 42.

For example, an alkali metal such as lithium or cesium may be used as the electron donating material. Also, for example, lithium fluoride, a lithium complex, cesium carbonate, a cesium complex, or the like may be used as the electron donating material. In this case, the electron donating property may be obtained by containing a reducing material such as aluminum, magnesium, or calcium together. The electron donating material may be a hole transport material. As a hole transport material, an organic compound such as a triarylamine derivative, a phenylenediamine derivative, a triazole derivative, an oxadiazole derivative, an imidazole derivative, a pyrazoline derivative, a pyrazolone derivative, an oxazole derivative, a fluorenone derivative, a hydrazone derivative, a stilbene derivative, a phthalocyanine derivative, a porphyrin derivative, poly (vinylcarbazole), poly (silylene), poly (thiophene), or a conductive polymer may be used. Also, the electron donating materials may be included in electron transport materials. As the electron transport material, an oxadiazole derivative, an oxazole derivative, a thiazole derivative, a thiadiazole derivative, a pyrazine derivative, a triazole derivative, a triazine derivative, a perylene derivative, a quinoline derivative, a quinoxaline derivative, a fluorenone derivative, an anthrone derivative, a phenanthroline derivative, or an organometallic complex may be used. As the electron accepting material, for example, an inorganic material including a transition metal oxide such as molybdenum oxide may be used, or an organic material such as [dipyrazino[2,3-f:2′,3′-h]quinoxaline-2,3,6,7,10,11-hexacarbonitrile] may be used. The charge generation layer may be a layer containing a mixture of an electron accepting material and an electron donating material. Also, the charge generation layer may be a layer formed by stacking a layer containing an electron accepting material and a layer containing an electron donating material. That is, the charge generation layer 42 may have a single layer structure or a multilayer structure.

The organic layer 40 can be formed using a dry process such as a vacuum deposition method, an ionization deposition method, a sputtering method, or a plasma method. Instead of the dry process, a wet process that forms the organic layer 40 by dissolving the above-described material in an appropriate solvent and using a well-known coating method (for example, a spin coating method, a dipping method, a casting method, a Langmuir-Blodgett method (LB method), an inkjet method, or the like) can be used. For example, when the organic layer 40 is formed using a vacuum deposition method or a coating method, crystallization of the organic layer 40 or the like hardly occurs, thereby obtaining the organic layer 40 with excellent temporal stability. Furthermore, for example, when the organic layer 40 is deposited using a coating method, it is possible to form the organic layer 40 in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them. One of these binder resins may be used singly as a homopolymer or a copolymer, or two or more of them may be used in combination. Furthermore, additives such as a well-known plasticizer, antioxidant, and an ultraviolet absorber may also be used as needed.

The organic layer 40 is arranged between the lower electrodes 2 and the upper electrode 5. As described above, the organic layer 40 may be continuously formed on the upper surface of the substrate 1 and may be shared by the plurality of organic light emitting elements 100. The entire organic layer 40 or part of it may be patterned for each organic light emitting element 100. The organic layer 40 may be formed to part of the outer peripheral region 2000 arranged on the periphery of the display region 3000.

The upper electrode 5 transmits light emitted from the light emitting layer of the organic layer 40. The upper electrode 5 may be made of a semi-transmissive material having a characteristic of transmitting part of light that has reached the surface and reflecting the remaining part of the light (that is, a transflective property). For the upper electrode 5, for example, a transparent conductive oxide such as ITO or IZO, a single metal such as Al, Ag, or gold (Au), an alkali metal such as lithium (Li) or cesium (Cs), an alkali earth metal such as magnesium (Mg), calcium (Ca), or barium (Ba), or an alloy material containing these metal materials. As the semi-transmissive material, an alloy containing Mg or Ag as a main component may be used. The main component can be a component having the highest percent concentration of mass among materials contained in the constituent element. The upper electrode 5 may have a stacked structure in which the layers using the above-described materials are stacked as long as it has an appropriate transmittance. The upper electrode 5 may be continuously formed on the upper surface of the substrate 1, as described above, and may be shared by the plurality of organic light emitting elements 100. Similar to the organic layer 40, the upper electrode 5 may be formed to part of the outer peripheral region 2000 arranged on the periphery of the display region 3000. In this case, the upper electrode 5 may be arranged up to the outside of the organic layer 40 in the outer peripheral region 2000, as will be described later. In the organic light emitting element 100, the lower electrode 2 can be an anode, and the upper electrode 5 can be a cathode. Alternatively, the lower electrode 2 can be a cathode, and the upper electrode 5 can be an anode.

As shown in FIG. 3, an insulating layer 3 may be provided to cover the outer peripheral portion of the lower electrode 2. In the insulating layer 3, an opening is formed to expose part of the lower electrode 2 and define a light emitting region 101 in which the lower electrode 2 and the organic layer 40 are in contact. The insulating layer 3 can be formed to make the light emitting region 101 have a desired shape correctly. If no insulating layer 3 is provided, the light emitting region 101 is defined by the shape of the lower electrode 2. The insulating layer 3 can be made of an inorganic material such as silicon nitride (SiN), silicon oxynitride (SiON), or silicon oxide (SiO). A known technique such as a sputtering method or a chemical vapor deposition method (CVD method) can be used to form the insulating layer 3. The insulating layer 3 can also be formed using an organic material such as an acrylic resin or a polyimide resin.

In the display region 3000 of the light emitting device 10, a protection layer 6 arranged to cover the upper electrode 5, a planarizing layer 7 arranged to cover the protection layer 6, and color filters 121 and microlenses 122 arranged on the planarizing layer 7 may further be arranged. The protection layer 6 protects the constituent elements arranged closer to the substrate 1 than the protection layer 6 from water in the atmosphere. The protection layer 6 can be made of an inorganic material such as SiN, SiON, or SiO. The protection layer 6 may be formed using an organic material such as various kinds of resins. The protection layer 6 may have a stacked structure of these materials. The planarizing layer 7 is arranged to suppress a step generated due to a difference in thickness of the insulating layer 30 (to be described later). The planarizing layer 7 may be formed using an inorganic material, as described above, or may be formed using an organic material. Each color filter 121 transmits light of color corresponding to optical interference caused by the thickness of the insulating layer 30. For example, a color filter 121a can transmit red light, a color filter 121b can transmit green light, and a color filter 121c can transmit blue light. The microlens 122 improves the use efficiency of light emitted from the light emitting layer included in the organic layer 40. The color filters 121 and the microlenses 122 can be formed using a known deposition method. A layer such as a planarizing layer may be arranged between the color filters 121 and the microlenses 122.

In this embodiment, a stacking portion 104 including the reflective layer 102 is arranged in the organic light emitting element 100. The stacking portion 104 includes a reflective region 105 in which the reflective layer 102 is arranged, and the reflective layer 102 is arranged to overlap the light emitting regions 101 of the lower electrodes 2 in orthogonal projection to the main surface 12 of the substrate 1. Furthermore, an electric corrosion suppression layer 103 is formed on the reflective layer 102. The electric corrosion suppression layer 103 of the stacking portion 104 includes an opening to expose the reflective layer 102 in at least a portion of a region overlapping the light emitting region 101 in orthogonal projection to the main surface 12 of the substrate 1. With this configuration, light emitted from the light emitting layer arranged in the organic layer 40 is transmitted through the lower electrode 2 and is efficiently reflected by the reflective layer 102. The size of the opening of the electric corrosion suppression layer 103 may be equal to the light emitting region 101 or may be larger than the light emitting region 101 from the viewpoint of improvement of light emission efficiency. In the configuration shown in FIG. 3, in orthogonal projection to the main surface 12 of the substrate 1, the light emitting region 101 is arranged to overlap the opening of the electric corrosion suppression layer 103, and the size of the opening of the electric corrosion suppression layer 103 is larger than the light emitting region 101.

Since the light reflected by the reflective layer 102 is extracted from the upper electrode 5 to the light emission side, the light emitting device 10 of this embodiment can obtain high light emission efficiency. The light emission side indicates the side of the upper electrode 5 with respect to the lower electrode 2.

For the reflective layer 102, for example, Ag or Al with a high reflectance may be used. For the electric corrosion suppression layer 103, for example, cobalt (Co), molybdenum (Mo), Pt, tantalum (Ta), titanium (Ti), titanium nitride (TiN), tungsten (W), or the like may be used. Each of the reflective layer 102 and the electric corrosion suppression layer 103 may be made of an alloy or a compound. For example, a material containing Al as a main component may be used for the reflective layer 102, and a material containing Ti or TiN as a main component may be used for the electric corrosion suppression layer 103. Furthermore, the reflective layer 102 may be made of a material containing Al as a main component and containing copper (Cu). The electric corrosion suppression layer 103 may contain TiN as a main component. A barrier metal such as Ti or TiN may be provided on the side of the substrate 1 of the stacking portion 104.

The reflective layer 102 and the electric corrosion suppression layer 103 can be formed using a known film forming method such as a sputtering method, a CVD method, or an atomic layer deposition method (ALD method). The reflective layer 102 can be formed by depositing a material with a high reflectance on the substrate 1 and then performing patterning by a known etching process. The electric corrosion suppression layer 103 can also be formed by depositing a material on the substrate 1 and performing patterning by a known etching process. The opening of the electric corrosion suppression layer 103 provided in the stacking portion 104 can be formed by removing the electric corrosion suppression layer 103 by a known etching process.

In this embodiment, the insulating layer 30 functioning as an optical interference layer is arranged between the lower electrodes 2 and the reflective layer 102 of the stacking portion 104. By adjusting the thickness of the insulating layer 30, it is possible to optimize the optical distance between the reflective layer 102 and the light emitting layer included in the organic layer 40 of the organic light emitting element 100. This can improve the light emission efficiency of the light emitting device 10 using optical interference. The insulating layer 30 may have a single-layer structure or a stacked structure including a plurality of layers.

As shown in FIG. 3, the plurality of lower electrodes 2 include a lower electrode 2a and a lower electrode 2b adjacent to each other. Furthermore, the plurality of lower electrodes 2 include the lower electrode 2b and a lower electrode 2c adjacent to each other. At this time, with respect to the insulating layer 30, the thickness of the insulating layer 30 between the lower electrode 2a and a reflective layer 102a arranged in the organic light emitting element 100a is different from the thickness of the insulating layer 30 between the lower electrode 2b and a reflective layer 102b arranged in the organic light emitting element 100b. With respect to the insulating layer 30, the thickness of the insulating layer 30 between the lower electrode 2b and the reflective layer 102b arranged in the organic light emitting element 100b is different from the thickness of the insulating layer 30 between the lower electrode 2c and a reflective layer 102c arranged in the organic light emitting element 100c. Furthermore, as shown in FIG. 3, with respect to the insulating layer 30, the thickness of the insulating layer 30 between the lower electrode 2a and the reflective layer 102a arranged in the organic light emitting element 100a may be different from the thickness of the insulating layer 30 between the lower electrode 2c and the reflective layer 102c arranged in the organic light emitting element 100c.

By making the thickness of the insulating layer 30 different in each of the organic light emitting elements 100a, 100b, and 100c, it is possible to adjust the colors of light components emitted from the organic light emitting elements 100a, 100b, and 100c. The insulating layer 30 can have a stacked structure of a plurality of layers. For example, if the insulating layer 30 is made thinner in an order of the organic light emitting elements 100a, 100b, and 100c, insulating layers 31, 32, and 33 are provided as the insulating layer 30 between the lower electrode 2a and the reflective layer 102a arranged in the organic light emitting element 100a. The insulating layers 32 and 33 are provided between the lower electrode 2b and the reflective layer 102b arranged in the organic light emitting element 100b, and the insulating layer 33 is provided between the lower electrode 2c and the reflective layer 102c arranged in the organic light emitting element 100c. This can form the insulating layer 30 functioning as an optical adjustment layer.

The insulating layer 30 can be made of a material that is transparent to the light emitted from the light emitting layer arranged in the organic layer 40. For example, SiO, SiN, SiON, or the like can be used as the insulating layer 30 (insulating layers 31 to 33). In this case, the insulating layer can be formed using a known technique such as a sputtering method, a CVD method, or an ALD method.

As shown in FIGS. 2 and 3, the stacking portion 104 may include a pixel contact region 115 including a conductive pattern 112 that is insulated from the reflective region 105 and electrically connected to the lower electrode 2. The lower electrode 2 and the pixel contact region 115 (conductive pattern 112) may electrically be connected to each other. This allows the organic light emitting element 100 to supply an electric potential (for example, electric power supply) to the lower electrode 2 via the conductive pattern 112. For example, the lower electrode 2 is supplied with a signal corresponding to the emission intensity of the organic light emitting element 100.

As the pixel contact region 115, the same layer as the reflective layer 102 and the electric corrosion suppression layer 103 of the reflective region 105 may be used. That is, the conductive pattern 112 electrically connected to each of the plurality of lower electrodes 2 may be arranged between each of the plurality of lower electrodes 2 and the main surface 12 of the substrate 1, and the distance from the main surface 12 to the reflective layer 102 may be equal to the distance from the main surface 12 to the conductive pattern 112. In this case, the pixel contact region 115 includes the conductive pattern 112 of the same layer as the reflective layer 102 and an electric corrosion suppression layer 113 of the same layer as the electric corrosion suppression layer 103. Therefore, the main component of the reflective layer 102 can be the same as that of the conductive pattern 112. Similarly, the main component of the electric corrosion suppression layer 103 can be the same that of the electric corrosion suppression layer 113.

If the insulating layer 30 is provided, the lower electrode 2 and the pixel contact region 115 can electrically be connected to each other by forming a via hole in the insulating layer 30 and forming the conductor 11 in the via hole. For the conductor 11, the same material as that of the lower electrode 2 may be used. For the conductor 11, a known conductive material such as W, Ti, or TiN can be used. The lower electrode 2 and the pixel contact region 115 may be in contact with each other via the via hole. In a portion that is in contact with the conductor 11 in the pixel contact region 115, the electric corrosion suppression layer 113 can be arranged from the viewpoint of suppression of electric corrosion.

A region where the conductor 11 is arranged can be, for example, the pixel contact region 115 where the electric corrosion suppression layer 113 of the stacking portion 104 exists, as shown in FIGS. 2 and 3. When the pixel contact region 115 and the lower electrode 2 are in direct contact with each other, if a combination of the electric corrosion suppression layer 113 and the lower electrode 2 hardly causes Galvanic corrosion, the reliability of the light emitting device 10 is improved. For example, a material containing TiN as a main component may be used for the electric corrosion suppression layer 113 and ITO or IZO may be used for the lower electrode 2 (conductor 11).

FIG. 3 shows the organic light emitting element 100 using the reflective layer 102 and the insulating layer 30 functioning as an optical interference layer, but the configuration is not limited to this. The insulating layer 30 may have the same thickness across the organic light emitting elements 100a to 100c. In this case, the reflective layer 102 may not be arranged, and the lower electrode 2 may be made of a material with light reflectivity.

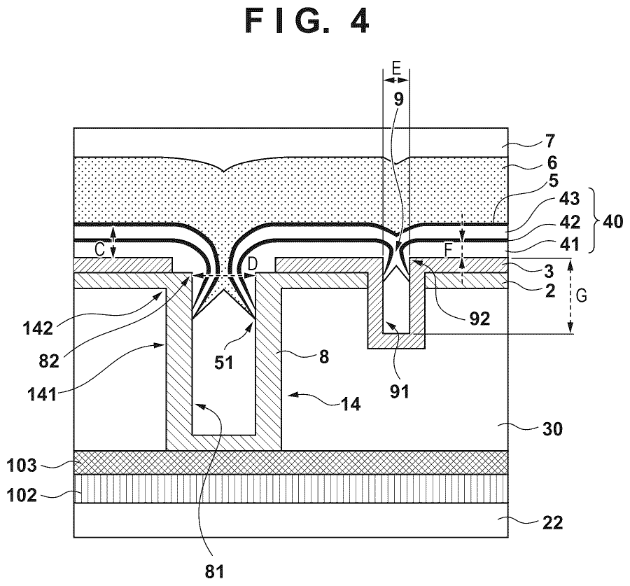

In the configuration shown in FIG. 3, a supply electrode 8 configured to supply an electric potential to the upper electrode 5 is arranged in the display region 3000. FIG. 4 is an enlarged view of a portion B surrounded by a dotted line in FIG. 3. The upper electrode 5 includes a contact portion 51 that is in contact with the supply electrode 8. The supply electrode 8 is a conductor in contact with the upper electrode 5 and is electrically connected to the reflective layer 102. Hence, the upper electrode 5 and the reflective layer 102 are set to an equipotential (for example, ground potential).

The supply electrode 8 can use the reflective layer 102 as a wiring pattern to electrically connect the upper electrode 5 and a power supply portion configured to supply power to each organic light emitting element 100. Therefore, it is unnecessary to form a wiring pattern for electrically connecting the upper electrode 5 in the same layer as the reflective layer 102 separately from the reflective layer 102. As a result, this is advantageous in implementing miniaturization (high resolution) of the display region 3000. As compared with a case where a wiring pattern is additionally formed in the same layer as the reflective layer 102, the reflective layer 102 can be used as a wiring pattern, and thus a creation process can be simplified.

Thus, a current flows not only to the upper electrode 5 but also the supply electrode 8 and the reflective layer 102 and reaches the power supply portion. For this reason, as compared to a case where the current flows only to the upper electrode 5, the resistance is low, and a voltage drop hardly occurs.

As shown in FIG. 3, in this embodiment, in orthogonal projection to the main surface 12 of the substrate 1, the light emitting device 10 includes, between each of the plurality of lower electrodes 2 and the contact portion 51, a portion in which the charge generation layer 42 is thinned. More specifically, in orthogonal projection to the main surface 12 of the substrate 1, the insulating layer 30 includes a trench 9 between each of the plurality of lower electrodes 2 and the contact portion 51. Part of the charge generation layer 42 sinks in the trench 9, and the charge generation layer 42 is thinned in the trench 9, as shown in FIG. 4. Here, “the charge generation layer 42 is thinned” indicates that the film thickness of the charge generation layer 42 is smaller with respect to the film thickness of the charge generation layer 42 in a portion (light emitting region 101) of the organic layer 40, which is in contact with the lower electrode 2, as a reference. Hence, it can also be said that the thickness of the charge generation layer 42 in the trench 9 is smaller than the thickness of the charge generation layer 42 on the plurality of lower electrodes 2. The reference of the film thickness of the charge generation layer 42 may be the film thickness of a portion of the charge generation layer 42, which extends in a direction parallel to the surface of the lower electrode 2 on the light emitting region 101. However, the reference of the film thickness of the charge generation layer 42 is not limited to this. If the charge generation layer 42 is formed on a relatively flat portion of the underlying layer (for example, the function layer 41), and the film thickness is even, the portion may be used as the reference of the film thickness of the charge generation layer 42. For example, a portion of the charge generation layer 42, which has an even film thickness on the peripheral edge portion of the trench 9, may be used as the reference of the film thickness of the charge generation layer 42.

The portion in which the charge generation layer 42 is thinned may have a concave shape like the trench 9 as shown in FIGS. 3 and 4, or may have a convex shape formed by the insulating layer 30 having a projecting portion. However, when the manufacturing steps are taken into consideration, a concave shape like the trench 9 is suitable. This is because since one inner wall of the trench 9 impedes incidence of material particles of the charge generation layer into the trench 9 in the step of forming the charge generation layer 42, the material particles are difficult to be deposited on the other inner wall facing the one, and the film thickness of the charge generation layer 42 is easily thinned.

In the trench 9, the charge generation layer 42 is thinned. As shown in FIG. 4, near the contact portion 51 of the upper electrode 5, the charge generation layer 42 may contact the supply electrode 8. Also, near the contact portion 51 of the upper electrode 5, the charge generation layer 42 may be close to or contact the upper electrode 5. Hence, a leakage current may flow between the charge generation layer 42 and the upper electrode 5. On the other hand, in this embodiment, when the charge generation layer 42 is thinned in the trench 9, the resistance of the charge generation layer 42 becomes high. This suppresses the leakage current between the charge generation layer 42 and the upper electrode 5. As a result, the light emission efficiency of the organic light emitting element 100 increases, and lowering of the display quality can be suppressed.

As shown in FIGS. 2 and 3, in the orthogonal projection to the main surface 12 of the substrate 1, the contact portion 51 of the upper electrode 5, which is in contact with the supply electrode 8, may be arranged between the lower electrode 2a of the organic light emitting element 100a and the lower electrode 2b of the organic light emitting element 100b. In this case, the contact portion 51 may at least partially be surrounded by the trench 9. As shown in FIG. 2, the contact portion 51 may completely be surrounded by the trench 9. This can more reliably suppress a path to flow the leakage current between the upper electrode 5 and the charge generation layer 42.

In orthogonal projection to the main surface 12 of the substrate 1, the supply electrode 8 may be arranged inside the region where the organic layer 40 is formed. In general, in the light emitting device 10 such as a fine organic EL device, the organic layer 40 is integrally formed on the entire display region 3000. This is because a method of separating an organic layer forming region for each organic light emitting element 100 (each pixel) requires a fine deposition process, and thus the yield may readily decrease due to the influence of a deposition positional deviation.

If the organic layer 40 is integrally formed on the entire display region 3000, when electrically connecting the upper electrode 5 and the supply electrode 8, the organic layer 40 tends to become an obstacle. On the other hand, as shown in FIGS. 3 and 4, in the portion of the supply electrode 8 in contact with the upper electrode 5, the supply electrode 8 is arranged in a concave shape like a via hole. With the concave shape, part of an inner wall along the side wall of the via hole of the supply electrode 8 is covered with the organic layer 40. In other words, in part of the inner wall of the supply electrode 8 along the side wall of the via hole, there is a portion where no organic layer 40 is formed. The upper electrode 5 is in contact with the region, that is not covered with the organic layer 40, of the inner wall of the supply electrode 8 along the side wall of the via hole (contact portion 51). This can electrically connect the upper electrode 5 and the supply electrode 8.

When forming the lower electrode 2, the supply electrode 8 can be formed from the same conductive film by performing patterning using an etching process. Therefore, the main component of the lower electrode 2 may be the same as that of the supply electrode 8. Furthermore, similar to the above-described connection between the lower electrode 2 and the conductive pattern 112, the reflective layer 102 and the supply electrode 8 may electrically be connected to each other via the electric corrosion suppression layer 103 for suppressing electric corrosion between the reflective layer 102 and the supply electrode 8.

In the configuration shown in FIGS. 2 and 3, the light emitting device 10 includes the supply electrode 8 between the organic light emitting element 100a and the organic light emitting element 100b. However, the configuration is not limited to this. For example, the supply electrode 8 surrounded by the trench 9 may be arranged between the organic light emitting element 100b and the organic light emitting element 100c as well. Arranging at least one supply electrode 8 in the display region 3000 suffices. For example, the supply electrode 8 may be arranged for every predetermined number of organic light emitting elements 100.

As shown in FIG. 4, the organic layer 40 may cover an upper end 82 of an inner wall 81, along a side wall 141 of a via hole 14, of the supply electrode 8. When the organic layer 40 covers the upper end 82 of the inner wall 81 of the supply electrode 8, the upper electrode 5 arranged on the organic layer 40 can be suppressed from being thinned and from not being formed partially in a portion bent from a direction parallel to the main surface 12 of the substrate 1 toward the inside of the via hole 14 of the supply electrode 8. As a result, it is possible to prevent the operating voltage of the light emitting device 10 from becoming high due to an increase in the resistance value of the upper electrode 5.

If a general semiconductor process is used, an upper end 142 of the side wall 141 of the via hole 14 has an angular shape. The upper end 82 of the inner wall 81 of the supply electrode 8 formed to cover the via hole 14 tends to have an angular shape. If the organic layer 40 is deposited not to be formed on the inner wall 81 of the supply electrode 8, the upper electrode 5 abruptly changes in shape in a portion bent toward the inner wall 81 of the supply electrode 8, and is thus thinned highly probably.

On the other hand, in this embodiment, when the organic layer 40 is formed on the angular upper end 82 of the inner wall 81 of the supply electrode 8, the upper surface of the organic layer 40 has a curved shape. Therefore, the change of the shape of the upper electrode 5 is gentle, and the upper electrode 5 is suppressed from being thinned and from not being formed partially.

As the effect produced when the organic layer 40 covers part of the inner wall 81 including the upper end 82 of the inner wall 81 of the supply electrode 8, the moisture blocking performance of the protection layer 6 is improved. Consider a case where the protection layer 6 is formed on the angular shape like the upper end 82 of the inner wall 81 of the supply electrode 8. In this case, during the growth process of the protection layer 6, the density of the protection layer 6 tends to decrease in a region where a portion of the protection layer 6 which is grown on the inner wall 81 of the supply electrode 8 and a portion of the protection layer 6 which is grown on the upper surface of the supply electrode 8 meet. Since the region where the density of the protection layer 6 has decreased reaches the lower portion of the protection layer 6, it will allow moisture to more easily enter the organic layer 40 via this low-density region. On the other hand, according to this embodiment, when the organic layer 40 covers a portion of the inner wall 81 including the upper end 82 of the inner wall 81 of the supply electrode 8, the upper surface of the organic layer 40 has a curved shape and has a structure in which its tilting angle continuously changes. Hence, the formation of a region where the grown protection layer 6 continuously meets on the different tilting angles and the density of the protective layer 6 has decreased is suppressed.

Here, a length D between upper sides facing each other in the upper end 82 of the supply electrode 8 may be longer than twice a thickness C of the organic layer 40. This suppresses a state in which the organic layer 40 is embedded in the inner wall 81 of the supply electrode 8, thereby making it possible to readily bring the upper electrode 5 and the supply electrode 8 into contact with each other.

The function layers 41 and 43 included in the organic layer 40 include the function layer 41 in contact with the lower electrode 2. In this case, a length E between upper sides 92 of the trench 9 facing each other may be twice or more of the thickness of the portion of the function layer 41 in contact with the lower electrode 2. In FIG. 4, the portion of the function layer 41 in contact with the lower electrode 2 is not illustrated, and a thickness F of a portion of the function layer 41 arranged outside the trench 9 is approximate to the thickness of a portion of the function layer 41 in contact with the lower electrode 2. This suppresses embedding of the function layer 41 in an inner wall 91 of the trench 9. That is, it is possible to suppress that the charge generation layer 42 is not sunk in the trench 9 and is not thinned.

Also, the length E between the upper sides 92 of the trench 9 facing each other may be smaller than a depth G of the trench 9. With this structure, when forming the charge generation layer 42, the material particles of the charge generation layer 42 hardly enter the trench 9, and the charge generation layer 42 is readily thinned.

The portion of the charge generation layer 42 sunk in the trench 9 may include a portion having a film thickness ½ or less the portion of the charge generation layer 42 arranged on the lower electrode 2. The film thickness of the charge generation layer 42 in the trench 9 is the thickness of each portion of the charge generation layer 42 in the normal direction to the surface. Furthermore, the charge generation layer 42 is not only thinned in the trench 9, and the portion of the charge generation layer 42 sunk in the trench 9 may include a discontinuous portion. When the continuity of the charge generation layer 42 is lost, and a portion where the charge generation layer 42 is not formed is generated, the resistance of the charge generation layer 42 can be made higher in the trench 9.

On the other hand, the function layer 43 may be formed to cover the trench 9. With this structure, the upper electrode 5 arranged on the function layer 43 is not sunk in the trench 9 and is readily continuously formed on the trench 9. As a result, an increase of the resistance of the upper electrode 5 due to the trench 9 can be suppressed.

The length D between the upper sides facing each other in the upper end 82 of the supply electrode 8, the length E between the upper sides 92 of the trench 9 facing each other, and the thickness C of the organic layer 40 may hold a relationship D>(2×C)>E. By this, the organic layer 40 is discontinuous in the supply electrode 8, the upper electrode 5 and the supply electrode 8 are in contact, and the organic layer 40 is difficult to be discontinuous in the trench 9. As a result, the upper electrode 5 reaches the supply electrode 8 without being discontinuous in the trench 9, and a current can be flowed between the upper electrode 5 and the supply electrode 8.

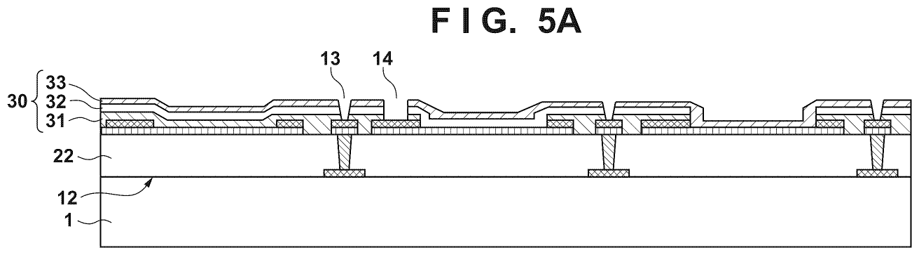

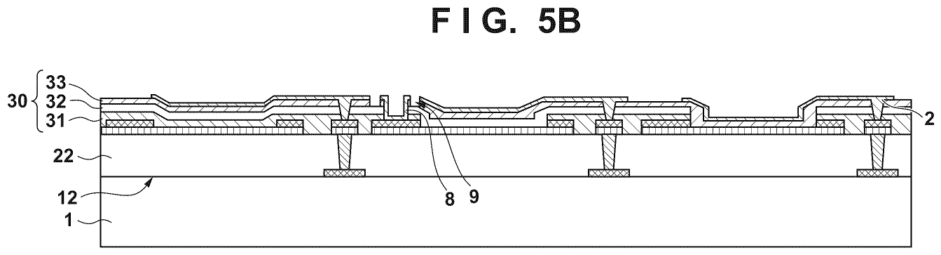

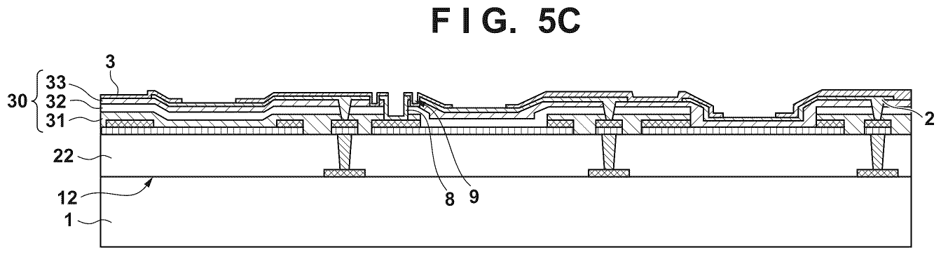

A method of manufacturing the light emitting device 10 will be described below with reference to FIGS. 5A to 5C. Note that the same processes as the processes of forming a general light emitting device including an organic light emitting element can be used up to the formation of the insulating layer 30 and a description thereof will be omitted here.

After the formation of the insulating layer 30, a via hole 13 and the via hole 14 extending through the insulating layer 30 are formed, as shown in FIG. 5A. Next, a conductive member is formed using the sputtering method or the like. At this time, in the via hole 14, the conductive member only covers the side wall 141 of the via hole 14, and is not embedded in the via hole 14. Next, by performing patterning using a photolithography method or the like, the lower electrode 2, the supply electrode 8, and the trench 9 are formed from the conductive member, as shown in FIG. 5B. The depth of the trench 9 can be controlled by controlling the etching time in patterning.

Subsequently, the insulating layer 3 is formed using the sputtering method or the like, and is patterned using the photolithography method or the like. At this time, the supply electrode 8 formed in the via hole 14 needs to be exposed. That is, it is necessary to etch the insulating layer 3 formed on the inner wall 81 of the supply electrode 8. Therefore, in the process of etching the insulating layer 3, isotropic dry etching or wet etching may be used. In this process, the insulating layer 3 is formed, as shown in FIG. 5C.

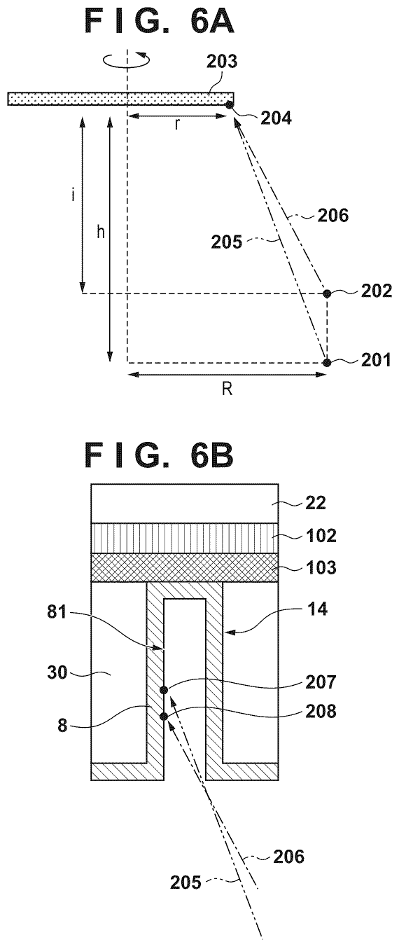

A method of forming the organic layer 40 and the upper electrode 5 will be described next with reference to FIGS. 6A and 6B. FIG. 6A is a view showing the positional relationship between the substrate 1 and deposition sources 201 and 202 at the time of forming the organic layer 40 and the upper electrode 5. The substrate 1 rotates at the time of forming the organic layer 40 and the upper electrode 5. The deposition source 202 for forming the organic layer 40 and the deposition source 201 for forming the upper electrode 5 are arranged at a position of a distance R in a direction parallel to the main surface 12 of the substrate 1 from the rotation center of the substrate 1. The deposition source 202 for forming the organic layer 40 is arranged at a position of a distance i in a direction orthogonal to the main surface 12 of the substrate 1 from the rotation center of the substrate 1. The deposition source 201 for forming the upper electrode 5 is arranged at a position of a distance h in the direction orthogonal to the main surface 12 of the substrate 1 from the rotation center of the substrate 1. At this time, the distance i is shorter than the distance h. That is, the deposition source 202 for forming the organic layer 40 is arranged at a position close to the substrate 1, as compared with the deposition source 201 for forming the upper electrode 5. Referring to FIG. 6A, the deposition sources 201 and 202 are arranged in one deposition device (chamber) for the descriptive purpose. However, FIG. 6A is a view showing the positional relationship between the substrate 1 and the deposition sources 201 and 202 at the time of forming the organic layer 40 and the upper electrode 5. Therefore, the deposition sources 201 and 202 may be arranged in different deposition devices (chambers) or in the same deposition device (chamber).

FIG. 6B is an enlarged view of the light emitting device 10, formed up to the process shown in FIG. 5A, at a position 204 (see FIG. 6A) of a distance r from the rotation center of the substrate 1. In the configuration described with reference to FIG. 6A, an incident angle 205 at which a deposition material enters from the deposition source 201 for forming the upper electrode 5 is different from an incident angle 206 at which a deposition material enters from the deposition source 202 for forming the organic layer 40. This causes the deposition material of the upper electrode 5 to reach a position 207 deeper than a position 208 of the limit depth up to which the deposition material of the organic layer 40 enters the via hole 14. This allows the upper electrode 5 to be in contact with the inner wall 81 of the supply electrode 8. A case where a deposition method is used as the method of forming the organic layer 40 has been explained. However, for example, the organic layer 40 may be formed using a laser ablation method or the like. After the organic layer 40 and the upper electrode 5 are formed, the protection layer 6 and the like are sequentially formed. As for these processes, the same processes as the processes of forming a general light emitting device including an organic light emitting element can be used, and a description thereof will be omitted here.

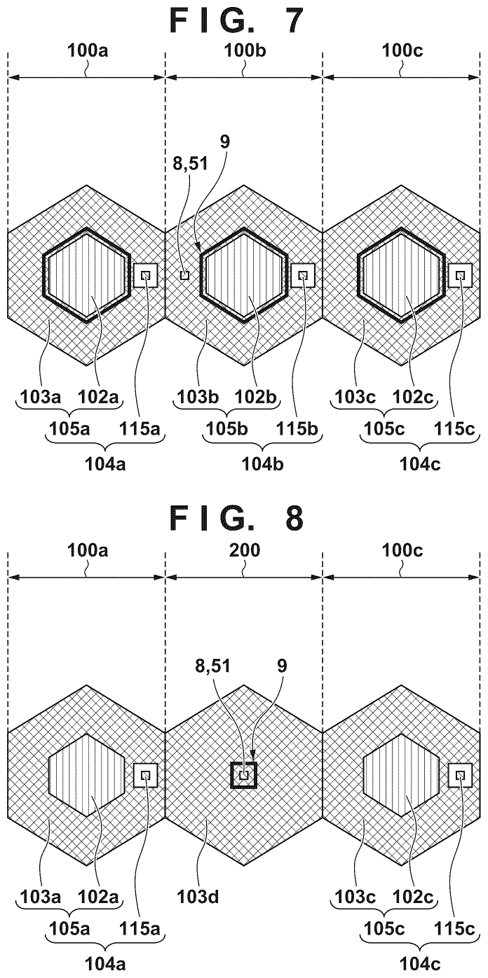

FIG. 7 is a view showing a modification of the configuration shown in FIG. 2. In the configuration shown in FIG. 7, in orthogonal projection to the main surface 12 of the substrate 1, portions (light emitting regions 101) of the organic layer 40 in contact with the plurality of lower electrodes 2 are at least partially surrounded by the trenches 9. As shown in FIG. 7, the trench 9 may completely surround the light emitting region 101. Here, the light emitting region 101 is arranged inside the electric corrosion suppression layer 103, as shown in FIG. 3. The configuration other than the arrangement of the trenches 9 may be the same as the configuration shown in FIGS. 2 and 3.

When the trench 9 surrounds the light emitting region 101, not only the leakage current between the upper electrode 5 and the charge generation layer 42 but also the leakage current flowing between the organic light emitting elements 100 adjacent to each other via the charge generation layer 42 can be suppressed. For this reason, color mixture between the organic light emitting elements 100 adjacent to each other can be suppressed, high color purity is implemented, and the display quality of the light emitting device 10 is improved. In the configuration shown in FIG. 7, in orthogonal projection to the main surface 12 of the substrate 1, the supply electrode 8 is not surrounded by the trench 9. However, an additional trench 9 may be arranged to surround the contact portion 51 (supply electrode 8).

FIG. 8 is a view showing a modification of the configuration shown in FIG. 2. In the configuration shown in FIG. 8, the organic light emitting element 100b changes to a potential supply portion 200, and the supply electrode 8 is arranged at the center of the potential supply portion 200, as compared to the configuration shown in FIG. 2. The configuration other than these can be the same as the above-described configuration shown in FIGS. 2 and 3. In the potential supply portion 200, the opening of the electric corrosion suppression layer 103d is not formed, and the lower electrode 2, the opening (light emitting region 101) of the insulating layer 3, the conductor 11, the conductive pattern 112, and the electric corrosion suppression layer 113 may not be formed. Even in the configuration shown in FIG. 8, since the contact portion 51 (supply electrode 8) is surrounded by the trench 9, the leakage current between the upper electrode 5 and the charge generation layer 42 can be suppressed, as in the above-described case.

In the potential supply portion 200, since components necessary for light emission of the light emitting layer need not always be arranged, the space to arrange the supply electrode 8 can readily be formed. For this reason, the configuration shown in FIG. 8 is suitable for miniaturization of the organic light emitting element 100.

In the configuration shown in FIG. 8, if the light emission colors of the organic light emitting elements 100 (sub-pixels) are four colors including red, green, blue, and white, the organic light emitting element 100 that emits white light may be used as the potential supply portion 200. This is because white can be output using the red, green, and blue organic light emitting elements 100. Arranging at least one potential supply portion 200 in the display region 3000 suffices. For example, the potential supply portion 200 may be arranged for every predetermined number of organic light emitting elements 100.

Here, in the configuration shown in FIGS. 2, and 3, the center distance between the lower electrode 2a of the organic light emitting element 100a and the lower electrode 2b of the organic light emitting element 100b with the supply electrode 8 arranged therebetween equals the center distance between the lower electrode 2b of the organic light emitting element 100b and the lower electrode 2c of the organic light emitting element 100c with no supply electrode 8 arranged therebetween. On the other hand, in the configuration shown in FIG. 7, the center distance between the lower electrode 2a of the organic light emitting element 100a and the lower electrode 2c of the organic light emitting element 100c with the supply electrode 8 arranged therebetween can be longer than the center distance between the lower electrode 2 of the organic light emitting element 100 and the lower electrode 2 of the organic light emitting element 100 with no supply electrode 8 arranged therebetween. For example, the center distance between the lower electrode 2a of the organic light emitting element 100a and the lower electrode 2c of the organic light emitting element 100c with the supply electrode 8 arranged therebetween can be twice as long as the center distance between the lower electrodes of the organic light emitting elements 100 with no supply electrode 8 arranged therebetween.

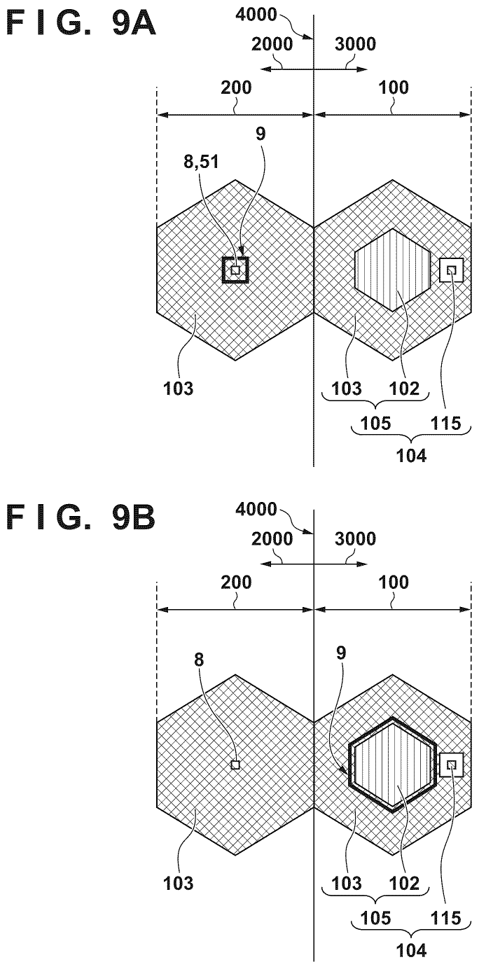

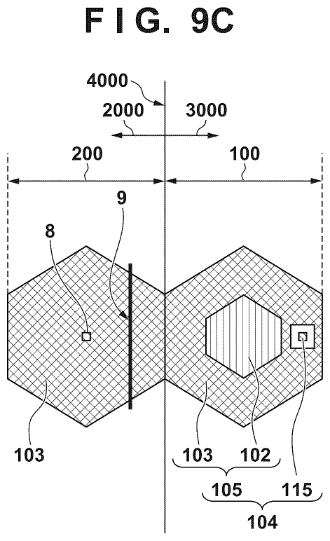

FIGS. 9A to 9C are views each showing the configuration of the light emitting device 10 that includes the potential supply portion 200 at a position different from the configuration shown in FIG. 8. In the configuration shown in FIG. 8, an example in which the potential supply portion 200 is arranged between the organic light emitting elements 100 arranged in the display region 3000 has been described. However, the potential supply portion 200 may be arranged in the outer peripheral region 2000.

A boundary line 4000 shown in FIG. 9A is a line indicating the boundary between the display region 3000 and the outer peripheral region 2000. As described above, in orthogonal projection to the main surface 12 of the substrate 1, the organic layer 40 and the upper electrode 5 are arranged up to the outer peripheral region 2000 outside the display region 3000 in which the plurality of lower electrodes 2 are arranged. In this case, in orthogonal projection to the main surface 12 of the substrate 1, the contact portion 51 may be arranged in a region where the organic layer 40 is arranged in the outer peripheral region 2000 and may also be at least partially surrounded by the trench 9. As shown in FIG. 9A, the trench 9 may completely surround the contact portion 51. Here, a structure having the same shape as the lower electrode 2 in the display region 3000 is sometimes arranged in the outer peripheral region 2000 as well (for example, a dummy region 500 to be described later). In a configuration in which no signal is supplied to the structure, like the lower electrode 2, the structure will not be referred to as the lower electrode 2 in the present disclosure. An example is a configuration in which the light emitting layer arranged in the organic layer 40 cannot be caused to emit light because, for example, no wiring pattern is electrically connected to the structure.

In the light emitting device 10, in some cases, the upper electrode 5 is arranged in the outer peripheral region 2000 up to the outside of the organic layer 40, and the supply electrode 8 (contact portion 51) is arranged outside the formation region of the organic layer 40. To the contrary, in the configuration shown in FIG. 9A, since the supply electrode 8 is provided in the formation region of the organic layer 40, the chip size can be made small. This makes it possible to, for example, obtain more chips from one wafer and reduce the cost per chip. Even in the configuration shown in FIG. 9A, since the contact portion 51 is surrounded by the trench 9, the leakage current between the upper electrode 5 and the charge generation layer 42 can be suppressed, as in the above-described case.

As shown in FIG. 9B, the potential supply portion 200 (contact portion 51) may be arranged in the outer peripheral region 2000, and in orthogonal projection to the main surface 12 of the substrate 1, a portion (light emitting region 101) of the organic layer 40 in contact with the lower electrode 2 may be surrounded by the trench 9. This makes it possible to suppress the leakage current between the organic light emitting elements 100, like the configuration shown in FIG. 7. Also, as shown in FIG. 9C, the potential supply portion 200 (contact portion 51) may be arranged in the outer peripheral region 2000, and the trench 9 may be arranged along the boundary line 4000. For example, the display region 3000 may at least partially be surrounded by the trench 9, or the trench 9 may completely surround the display region 3000. Also, the configurations shown in FIGS. 9A to 9C may be used in combination, or these may be combined with the above-described configurations. For example, the contact portion 51 may be arranged in both the display region 3000 and the outer peripheral region 2000.

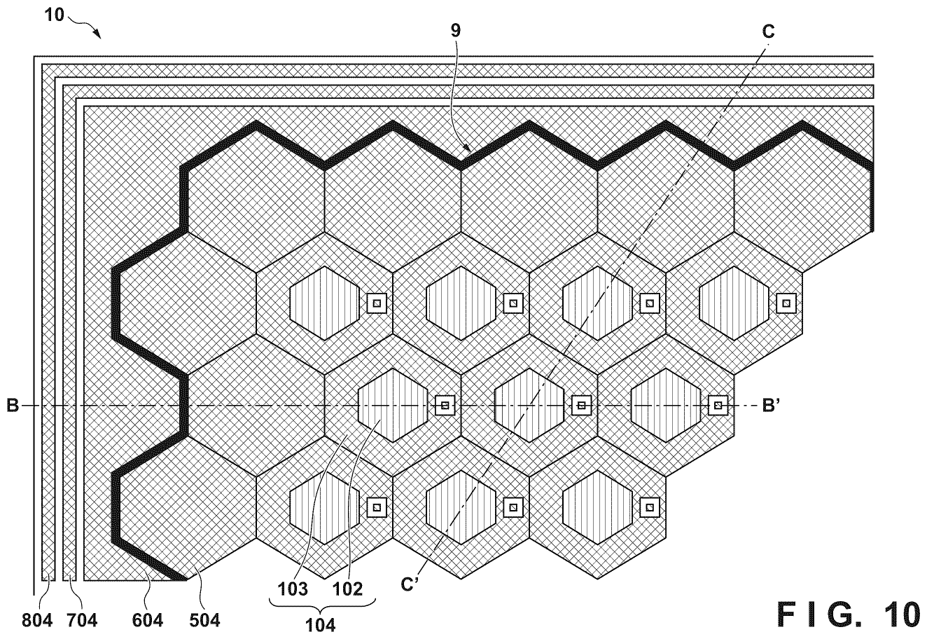

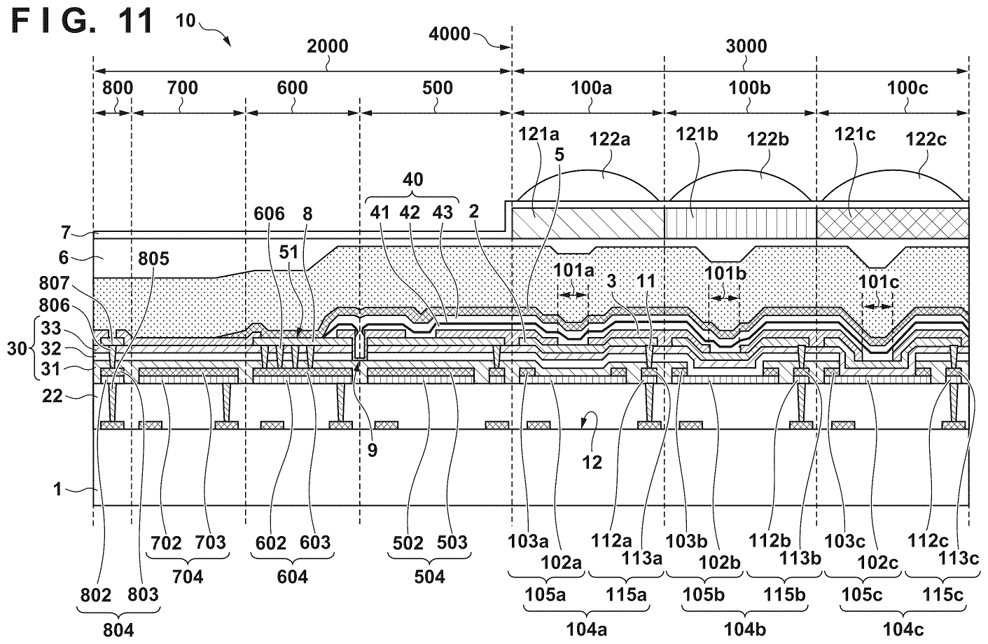

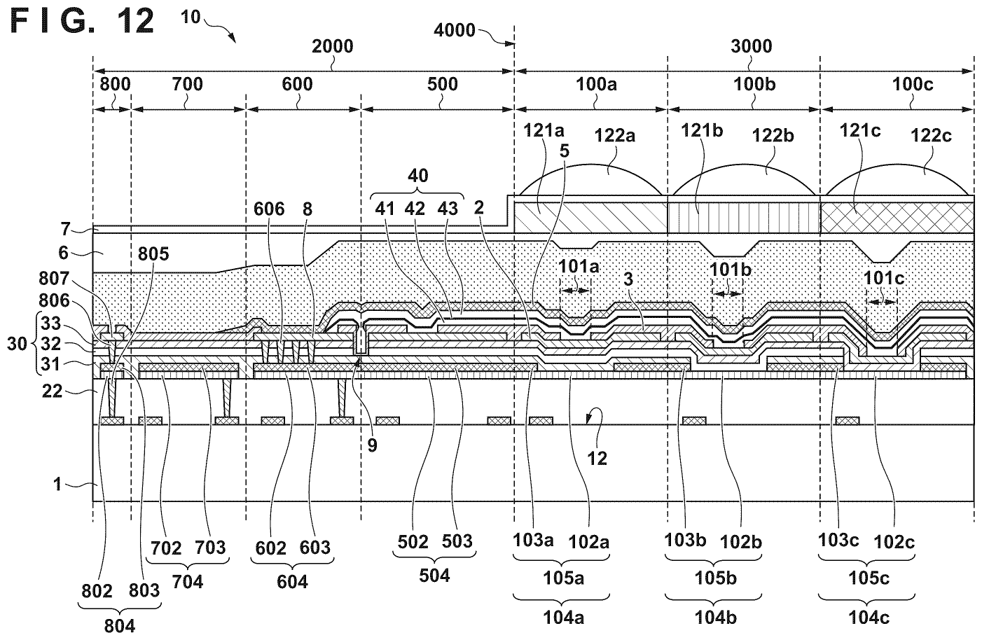

A configuration different from the above-described configurations of the light emitting device 10 will be described with reference to FIGS. 10 to 12. FIG. 10 is a plan view showing an example of the configuration of the light emitting device 10 according to this embodiment. FIGS. 11 and 12 are sectional views taken along a line B-B′ and a line C-C′ in FIG. 10, respectively.

As shown in FIGS. 10 to 12, in orthogonal projection to the main surface 12 of the substrate 1, the organic layer 40 and the upper electrode 5 are arranged up to the outer peripheral region 2000 outside the display region 3000 in which the plurality of lower electrodes 2 are arranged, and the upper electrode 5 is arranged further up to the outside of the organic layer 40 in the outer peripheral region 2000. At this time, the contact portion 51 of the upper electrode 5 in contact with the supply electrode 8 is arranged in a region of the outer peripheral region 2000 outside the organic layer 40, and the display region 3000 is at least partially surrounded by the trench 9. The trench 9 may completely surround the display region 3000. It can also be said that the trench 9 is arranged between the contact portion 51 in which the upper electrode 5 contacts the supply electrode 8 and the light emitting region 101 in which the lower electrode 2 and the organic layer 40 in the organic light emitting element 100 on the outermost periphery of the display region 3000 are in contact.

At the end portion of the formation region of the organic layer 40, the charge generation layer 42 and the upper electrode 5 can be in contact, as shown in FIGS. 11 and 12. Since the resistance of the charge generation layer 42 is high in the trench 9, the leakage current between the upper electrode 5 and the charge generation layer 42 can be suppressed. That is, lowering of the display quality in the display region 3000 can be suppressed. In a case where the trench 9 is not provided, to prevent the charge generation layer 42 and the upper electrode 5 from being in contact, the function layer 43 needs to be arranged such that the formation region of the function layer 43 continues up to the outside of the formation region of the charge generation layer 42. In this embodiment, since the formation regions of the layers of the organic layer 40 can be identical, the chip size can be made small. This makes it possible to obtain more chips from one wafer and reduce the cost per chip.

In the configuration shown in FIGS. 10 to 12, the contact portion 51 (supply electrode 8) of the upper electrode 5 is not provided in the display region 3000. However, the present invention is not limited to this, and the contact portion 51 (supply electrode 8) may be arranged in the display region 3000 in addition to the configuration shown in FIGS. 10 to 12, like the configurations shown in FIGS. 2 to 8. In this case, the trench 9 is arranged in the display region 3000 as well, like the configurations shown in FIGS. 2 to 8.

In the configuration shown in FIGS. 10 to 12, the dummy region 500 is provided in the outer peripheral region 2000. In the dummy region 500, a stacking portion 504 is arranged. The stacking portion 504 can include, between the interlayer insulating layer 22 and the insulating layer 30, a reflective layer 502 whose main component is the same as the reflective layer 102 of the stacking portion 104, and between the reflective layer 502 and the insulating layer 30, an electric corrosion suppression layer 503 whose main component is the same as the electric corrosion suppression layer 103. When the dummy region 500 is arranged, a structure whose configuration is at least partially the same as the organic light emitting element 100 arranged in the display region 3000 is arranged in a region adjacent to the display region 3000. This suppresses variations in the manufacture of the organic light emitting elements 100 in the display region 3000. For example, as shown in FIGS. 11 and 12, a structure equivalent to the lower electrode 2, the insulating layer 30, the organic layer 40, the upper electrode 5, and the like can be formed in the dummy region 500, as in the display region 3000.

The stacking portion 504 in the dummy region 500 may electrically be insulated from the stacking portion 104. Also, in the organic light emitting element 100, if the pixel contact region 115 is electrically insulated from the reflective region 105, as shown in FIG. 12, the stacking portion 504 in the dummy region 500 and the reflective region 105 in the display region 3000 may electrically be connected.

The stacking portion 504 can be formed at the same time as the formation of the stacking portion 104. From the viewpoint of suppressing process variations in depositing or patterning the reflective layers 102 and 502 and the electric corrosion suppression layers 103 and 503, the distance between the stacking portion 104 and the substrate 1 may substantially equal the distance between the stacking portion 504 and the substrate 1. Also, the film thickness of the reflective layer 102 and that of the reflective layer 502 may substantially equal, and the film thickness of the electric corrosion suppression layer 103 and that of the electric corrosion suppression layer 503 may substantially equal.

In the configuration shown in FIGS. 10 to 12, an upper electrode contact region 600 is provided in the outer peripheral region 2000. In the upper electrode contact region 600, a stacking portion 604 is arranged. The stacking portion 604 can include, between the interlayer insulating layer 22 and the insulating layer 30, a reflective layer 602 whose main component is the same as the reflective layer 102 of the stacking portion 104, and between the reflective layer 602 and the insulating layer 30, an electric corrosion suppression layer 603 whose main component is the same as the electric corrosion suppression layer 103. The upper electrode contact region 600 is a region that is in electrical contact with the upper electrode 5. The upper electrode 5 and the stacking portion 604 may be in direct contact with each other, or a member that relays electrical connection may exist between the upper electrode 5 and the stacking portion 604. For example, as shown in FIGS. 11 and 12, when a plug 606 and the supply electrode 8 whose main component is the same as the lower electrode 2 are arranged on the stacking portion 604 in the upper electrode contact region 600, the upper electrode 5 and the stacking portion 604 can electrically be connected. For the plug 606, the same material as the supply electrode 8 may be used or, for example, another material such as W, TiN, or Ti may be used.

Also, in the organic light emitting element 100, if the pixel contact region 115 is electrically insulated from the reflective region 105, as shown in FIG. 12, the stacking portion 604 in the upper electrode contact region 600 and the reflective region 105 in the display region 3000 may electrically be connected. In this case, the upper electrode 5 and the reflective region 105 are at an equipotential. Furthermore, in the organic light emitting element 100, if the pixel contact region 115 is electrically insulated from the reflective region 105, the stacking portion 604 in the upper electrode contact region 600, the stacking portion 504 in the dummy region 500, and the reflective region 105 in the display region 3000 may electrically be connected. In this case, the upper electrode 5, the stacking portion 604, the stacking portion 504, and the reflective region 105 are at an equipotential.

The stacking portion 604 can be formed at the same time as the formation of the stacking portion 104. In other words, the stacking portion 604 can be formed as the same time as the stacking portion 104 and the stacking portion 504. From the viewpoint of suppressing process variations in depositing or patterning the reflective layers 102 and 602 and the electric corrosion suppression layers 103 and 603, the distance between the stacking portion 104 and the substrate 1 may substantially equal the distance between the stacking portion 604 and the substrate 1. Also, the film thickness of the reflective layer 102 and that of the reflective layer 602 may substantially equal, and the film thickness of the electric corrosion suppression layer 103 and that of the electric corrosion suppression layer 603 may substantially equal.

In the configuration shown in FIGS. 10 to 12, a wiring region 700 is provided in the outer peripheral region 2000. In the wiring region 700, a stacking portion 704 is arranged. The stacking portion 704 can include, between the interlayer insulating layer 22 and the insulating layer 30, a reflective layer 702 whose main component is the same as the reflective layer 102 of the stacking portion 104, and between the reflective layer 702 and the insulating layer 30, an electric corrosion suppression layer 703 whose main component is the same as the electric corrosion suppression layer 103. The wiring region 700 is a region in which the stacking portion 704 electrically insulated from the upper electrode 5 is used as a wiring pattern. The application purpose of the wiring pattern is not particularly limited.

The stacking portion 704 can be formed at the same time as the formation of the stacking portion 104. In other words, the stacking portion 704 can be formed as the same time as the stacking portion 104, the stacking portion 504, and the stacking portion 604. From the viewpoint of suppressing process variations in depositing or patterning the reflective layers 102 and 702 and the electric corrosion suppression layers 103 and 703, the distance between the stacking portion 104 and the substrate 1 may substantially equal the distance between the stacking portion 704 and the substrate 1. Also, the film thickness of the reflective layer 102 and that of the reflective layer 702 may substantially equal, and the film thickness of the electric corrosion suppression layer 103 and that of the electric corrosion suppression layer 703 may substantially equal.

In the configuration shown in FIGS. 10 to 12, a moisture-proof region 800 is provided in the outer peripheral region 2000. In the moisture-proof region 800, a stacking portion 804 is arranged. The stacking portion 804 can include, between the interlayer insulating layer 22 and the insulating layer 30, a reflective layer 802 whose main component is the same as the reflective layer 102 of the stacking portion 104, and between the reflective layer 802 and the insulating layer 30, an electric corrosion suppression layer 803 whose main component is the same as the electric corrosion suppression layer 103. The moisture-proof region 800 is provided on the outermost periphery of the light emitting device 10 and is arranged for the purpose of preventing water from entering from the periphery of the light emitting device 10. Hence, from the viewpoint of moisture proofing, the stacking portion 804 may continuously be formed on the outermost periphery of the light emitting device 10. Also, in the moisture-proof region 800, a plug 805 provided between the stacking portion 804 and the substrate 1 or a plug 806 provided on the stacking portion 804 may continuously be formed on the outermost periphery of the light emitting device 10. Furthermore, an adhering portion 807 may continuously be formed, in the upper portion of the plug 806, on the outermost periphery of the light emitting device 10. When arranging the protection layer 6, the protection layer 6 and the adhering portion 807 may be in contact. The adhering portion 807 can be made of the same material whose main component is the same as the lower electrode 2. In other words, the adhering portion 807 can be formed at the same time as the lower electrode 2.

The stacking portion 804 can be formed at the same time as the formation of the stacking portion 104. In other words, the stacking portion 804 can be formed as the same time as the stacking portion 104, the stacking portion 504, the stacking portion 604, and the stacking portion 704. From the viewpoint of suppressing process variations in depositing or patterning the reflective layers 102 and 802 and the electric corrosion suppression layers 103 and 803, the distance between the stacking portion 104 and the substrate 1 may substantially equal the distance between the stacking portion 804 and the substrate 1. Also, the film thickness of the reflective layer 102 and that of the reflective layer 802 may substantially equal, and the film thickness of the electric corrosion suppression layer 103 and that of the electric corrosion suppression layer 803 may substantially equal.

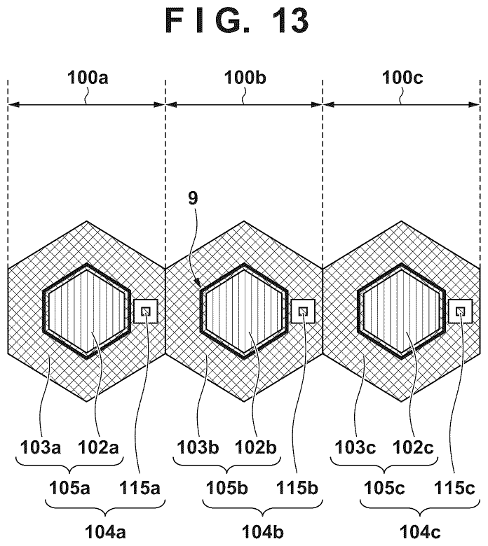

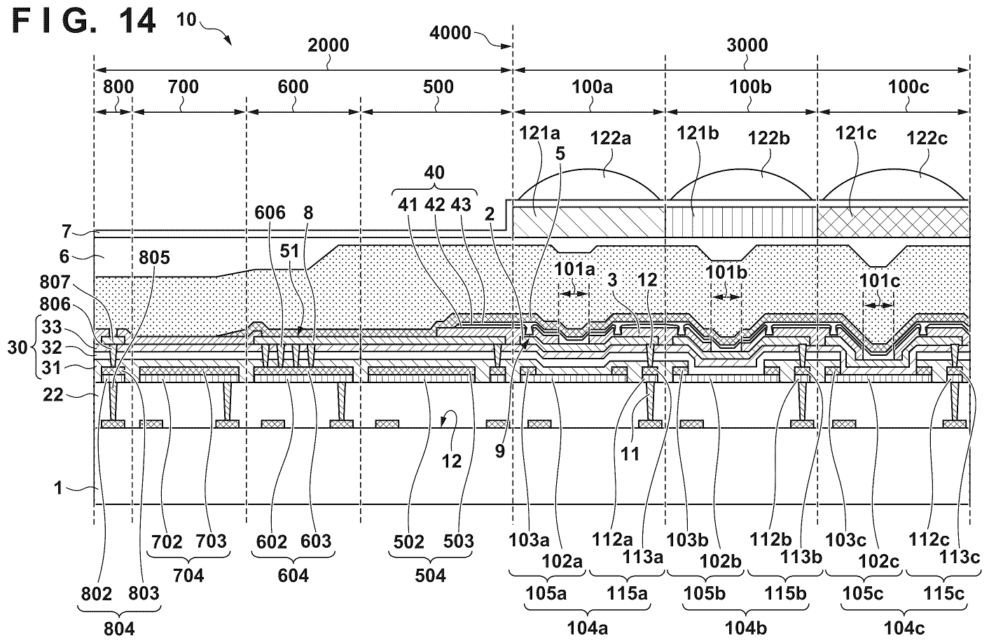

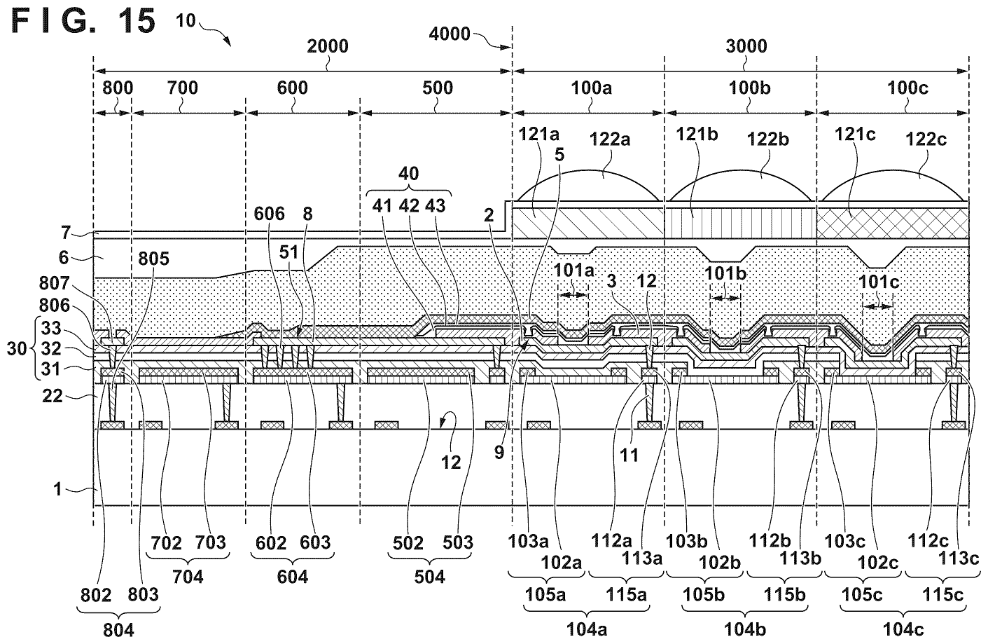

FIGS. 13 to 15 are views showing a modification of the light emitting device 10 described with reference to FIGS. 10 to 12. FIG. 13 is a plan view showing an example of the configuration of the light emitting device 10 according to this embodiment. FIG. 14 is a plan view showing an example of the configuration of the light emitting device 10 according to this embodiment. FIG. 15 is a view showing a modification of the sectional view of FIG. 14.

In the configuration shown in FIGS. 13 to 15, like the configuration shown in FIGS. 10 to 12, in orthogonal projection to the main surface 12 of the substrate 1, the contact portion 51 of the upper electrode 5 in contact with the supply electrode 8 is arranged in a region of the outer peripheral region 2000 outside the organic layer 40. On the other hand, in the configuration shown in FIGS. 10 to 12, the trench 9 is arranged to surround the display region 3000. However, in the configuration shown in FIGS. 13 to 15, the trench 9 is arranged to surround a portion (light emitting region 101) of the organic layer 40 in contact with the lower electrode 2. This makes it possible to suppress not only the leakage current between the upper electrode 5 and the charge generation layer 42 but also the leakage current flowing between the organic light emitting elements 100 adjacent to each other via the charge generation layer 42, like the configuration shown in FIG. 7 described above. For this reason, color mixture between the organic light emitting elements 100 adjacent to each other can be suppressed, and high color purity is implemented.

As shown in FIG. 14, in the outer peripheral region 2000, the charge generation layer 42 may be in contact with the upper electrode 5. Also, as shown in FIG. 15, in the outer peripheral region 2000, the charge generation layer 42 may be in contact with the upper electrode 5 and the supply electrode 8. This sets the upper electrode 5 and the charge generation layer 42 at an equipotential outside the trench 9 arranged for each organic light emitting element 100 (in orthogonal projection to the main surface 12 of the substrate 1, on the side opposite to the light emitting region 101 of the trench 9). This can suppress a leakage current derived from the function layer 43 arranged between the upper electrode 5 and the charge generation layer 42.

Providing the trench 9 in which the charge generation layer 42 of the organic layer 40 sinks to increase the resistance of the charge generation layer 42 and suppress the leakage current generated by the arrangement of the charge generation layer 42 has been described above. However, suppression of the leakage current caused by the arrangement of the charge generation layer 42 is not limited to thinning of the charge generation layer 42 using the trench 9.

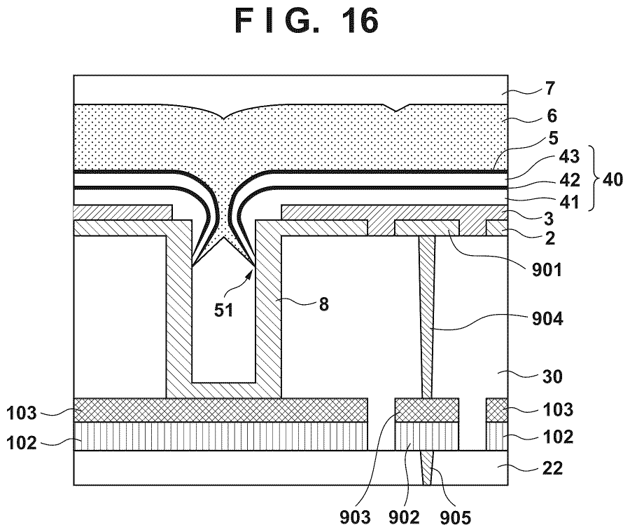

FIG. 16 is a view for explaining the light emitting device 10 including, in place of the trench 9, an electric field application electrode 901 configured to suppress the leakage current caused by the arrangement of the charge generation layer 42. As shown in FIG. 16, the electric field application electrode 901 configured to apply an electric field to the charge generation layer 42 is arranged between the insulating layer 30 and the organic layer 40 and, in orthogonal projection to the main surface 12 of the substrate 1, between the contact portion 51 and each of the plurality of lower electrodes 2. A predetermined electric potential is supplied to the electric field application electrode 901 via a plug 904, an electric corrosion suppression layer 903, a reflective layer 902, and a plug 905. The configuration other than these may be the same as each configuration of the light emitting device 10 described above, and a description thereof will be omitted here.

In the configuration shown in FIG. 16, when a predetermined electric potential is supplied to the electric field application electrode 901, the electric field can be applied between the electric field application electrode 901 and the upper electrode 5. By the electric field applied between the electric field application electrode 901 and the upper electrode 5, recombination of charges that flow, via the organic layer 40, from the region in which the lower electrode 2 and the organic layer 40 are in contact is promoted, and the charges are difficult to reach the supply electrode 8. This makes it possible to suppress not only the leakage current caused by the arrangement of the charge generation layer 42 with high conductivity in the organic layer 40 but also the leakage current caused by the function layers 41 and 43. During the operation of the light emitting device 10, a voltage equal to or more than a light emission threshold of the light emitting layer arranged in the organic layer 40 may be applied between the electric field application electrode 901 and the upper electrode 5. This facilitates charge recombination by the electric field.

The electric field application electrode 901 can be arranged at the same position as the above-described trench 9. Also, the electric field application electrode 901 and the trench 9 may be used in combination. Even in a case where the electric field application electrode 901 is used, it is possible to suppress the leakage current and suppress lowering of the display quality of the light emitting device 10, like the above-described configurations.

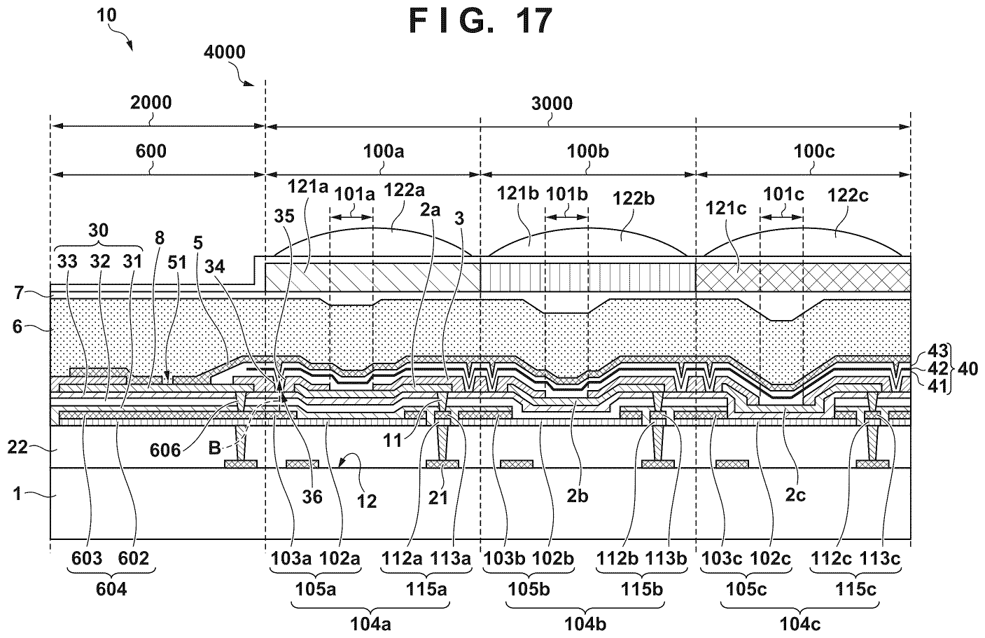

If the charge generation layer 42 is thinned by providing the trench 9, the organic layer 40 including not only the charge generation layer 42 but also the function layers 41 and 43 can be thinned. When the organic layer 40 is thinned, a leakage current is readily generated between the lower electrode 2 and the upper electrode 5 via the thinned portion of the organic layer 40. A modification of the above-described light emitting device 10 configured to suppress the leakage current between the lower electrode 2 and the upper electrode 5 via the organic layer 40 will be described below with reference to FIGS. 17 and 18. FIG. 17 is a sectional view showing an example of the configuration of the light emitting device 10 according to this embodiment, and FIG. 18 is a plan view showing an example of the configuration of the light emitting device 10. FIG. 17 shows a cross section taken along a line A-A′ in FIG. 18.

As shown in FIG. 17, on the surface of the insulating layer 3 facing the organic layer 40, tilting portions 34 and 35 having a tilt with respect to the main surface 12 of the substrate 1 are arranged. The tilting portions 34 and 35 may form the side walls of a trench 36 provided in the surface of the insulating layer 3. The trench 36 may be provided only in the insulating layer 3, as shown in FIG. 17. Also, for example, the trench 36 may be provided in the insulating layer 3 and the insulating layer 30. Furthermore, for example, the trench 36 may have the same configuration as the above-described trench 9.

In the organic layer 40, as described above, the charge generation layer 42 having a thin film thickness is readily formed on a portion of the insulating layer 3 arranged on the tilting portions 34 and 35 with respect to a flat portion parallel to the main surface 12 of the substrate 1. This can make the resistance of the charge generation layer 42 high. As a result, a crosstalk current between the organic light emitting elements 100 can be suppressed.

However, on a portion of the organic layer 40 arranged on the tilting portions 34 and 35 of the insulating layer 3, the layer thickness of the organic layer 40 also becomes thin. This may increase the leakage current between the lower electrode 2 and the upper electrode 5 via the organic layer 40. As shown in FIG. 17, conductive layers are arranged between the main surface 12 of the substrate 1 and the tilting portions 34 and 35 (trench 36) such that it overlaps the tilting portions 34 and 35 (trench 36) in orthogonal projection to the main surface 12 of the substrate 1. In this embodiment, the reflective layer 102 and the electric corrosion suppression layer 103 arranged in the reflective region 105 function as the conductive layers. The conductive layers (the reflective layer 102 and the electric corrosion suppression layer 103 arranged in the reflective region 105) are not electrically connected to any of the plurality of lower electrodes 2.

The reflective region 105 may electrically be connected to the upper electrode 5 via the stacking portion 604, the plug 606, the supply electrode 8, like a reflective region 105a shown in FIG. 17. That is, the electric potential of the conductive layers arranged between the main surface 12 of the substrate 1 and the tilting portions 34 and 35 (trench 36) may be the same as the electric potential of the upper electrode 5. Also, as shown in FIG. 18, the reflective regions 105 corresponding to the organic light emitting elements 100 may electrically be connected to each other. Accordingly, the electric potential of the reflective region 105 functioning as the conductive layer closest to the tilting portions 34 and 35, which is arranged at a position to overlap the tilting portions 34 and 35 in orthogonal projection to the main surface 12 of the substrate 1 equals the electric potential of the upper electrode 5.

The conductive layers (the reflective layer 102 and the electric corrosion suppression layer 103 arranged in the reflective region 105) have the same electric potential as the upper electrode 5. Since this can weaken the field strength in a direction B, which is applied to the organic layer 40 stacked on the tilting portions 34 and 35, the leakage current between the lower electrode 2 and the upper electrode 5 via the organic layer 40 can be suppressed. The electric field in the direction B, which is applied to the organic layer 40, promotes charge separation in the charge generation layer 42, and charges are generated. This is because if many charges exist in the organic layer 40 having a thin layer thickness and formed on the tilting portions 34 and 35, the charges flow up to a counter electrode via the thin organic layer 40 without recombining and form a leakage current source between the lower electrode 2 and the upper electrode 5. When the field strength in the direction B is weakened, the leakage current between the lower electrode 2 and the upper electrode 5 via the organic layer 40 is suppressed. Here, the electric field in the direction B is shown using, as an example, the direction of the electric field that promotes the leakage current in a case where the lower electrode 2 serves as an anode, and the upper electrode 5 serves as a cathode. If the lower electrode 2 serves as a cathode, and the upper electrode 5 serves as an anode, the direction B faces downward, opposing to the direction shown in FIG. 3.

Described above is causing the reflective region 105 functioning as a conductive layer to have the same electric potential as the upper electrode 5, but the electric potential of the conductive layer need not always the same as the upper electrode 5. For example, the conductive layer (reflective region 105) may be in a floating state. Alternatively, for example, the conductive layer (reflective region 105) may be connected to a predetermined power supply, and a predetermined electric potential may be supplied from the power supply to the conductive layer. More specifically, if the following electric potential relationship is held, the effect of suppressing the leakage current between the lower electrode 2 and the upper electrode 5 via the organic layer 40 can be obtained.

If the lower electrode 2 serves as an anode, and the upper electrode 5 serves as a cathode, the electric potential of the conductive layer (reflective region 105) is set lower than that of the lower electrode 2. That is, letting V be the electric potential of the conductive layer, and V_{D} be the electric potential of the lower electrode, a relationship given by

$$V < {V}_{D} \qquad ( 1 )$$

may hold. Thus, the electric potential difference of the conductive layer (reflective region 105) with respect to the upper electrode 5 is smaller than the electric potential difference of the lower electrode 2 with respect to the upper electrode 5. As a result, the field strength in the portion of the organic layer 40 arranged on the tilting portions 34 and 35 is improved in the direction of suppressing the leakage current between the lower electrode 2 and the upper electrode 5 via the organic layer 40.

If the lower electrode 2 serves as a cathode, and the upper electrode 5 serves as an anode, the electric potential of the conductive layer (reflective region 105) is set higher than that of the lower electrode 2. That is, letting V be the electric potential of the conductive layer, and VD be the electric potential of the lower electrode, a relationship given by

$$V > {V}_{D} \qquad ( 2 )$$

may hold. Thus, the electric potential difference of the conductive layer (reflective region 105) with respect to the upper electrode 5 is larger than the electric potential difference of the lower electrode 2 with respect to the upper electrode 5. As a result, the field strength in the portion of the organic layer 40 arranged on the tilting portions 34 and 35 is improved in the direction of suppressing the leakage current between the lower electrode 2 and the upper electrode 5 via the organic layer 40.

The difference between the electric potential of the conductive layer (reflective region 105) and the electric potential of the upper electrode 5 may be smaller than the difference between the electric potential of the conductive layer and the electric potential of the lower electrode 2. This can make the field strength applied between the upper electrode 5 and the conductive layer small. For example, the difference between the electric potential of the conductive layer and the electric potential of the upper electrode 5 may be 1 V or less. Furthermore, as described above, the electric potential of the conductive layer and the electric potential of the upper electrode 5 may equal.

The configuration shown in FIG. 17 indicates the top emission type light emitting device 10 that extracts light to a side opposite to the substrate 1 with respect to the organic layer 40. However, even in a bottom emission type light emitting device that extracts light to the side of the substrate 1, the electrode on the side of the substrate 1 with respect to the organic layer 40 can be considered as the lower electrode 2, and the electrode on the side opposite to the substrate 1 can be considered as the upper electrode 5. That is, even in the bottom emission type light emitting device, the same effect as described above can be obtained by arranging the tilting portions 34 and 35 and the conductive layer.

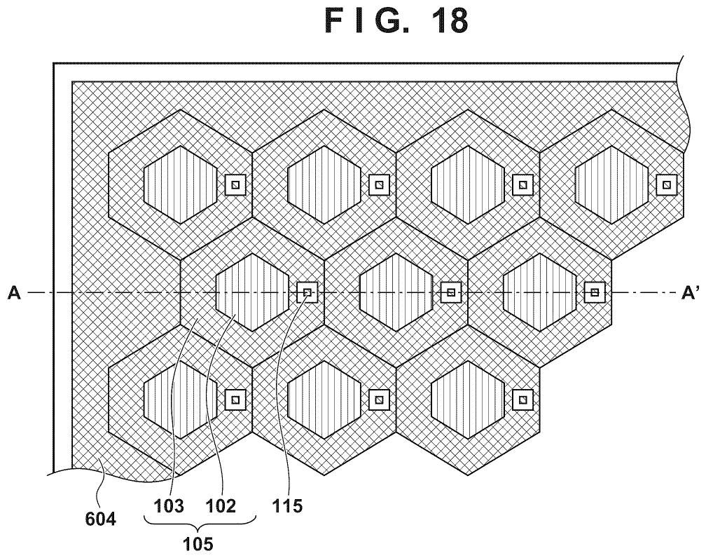

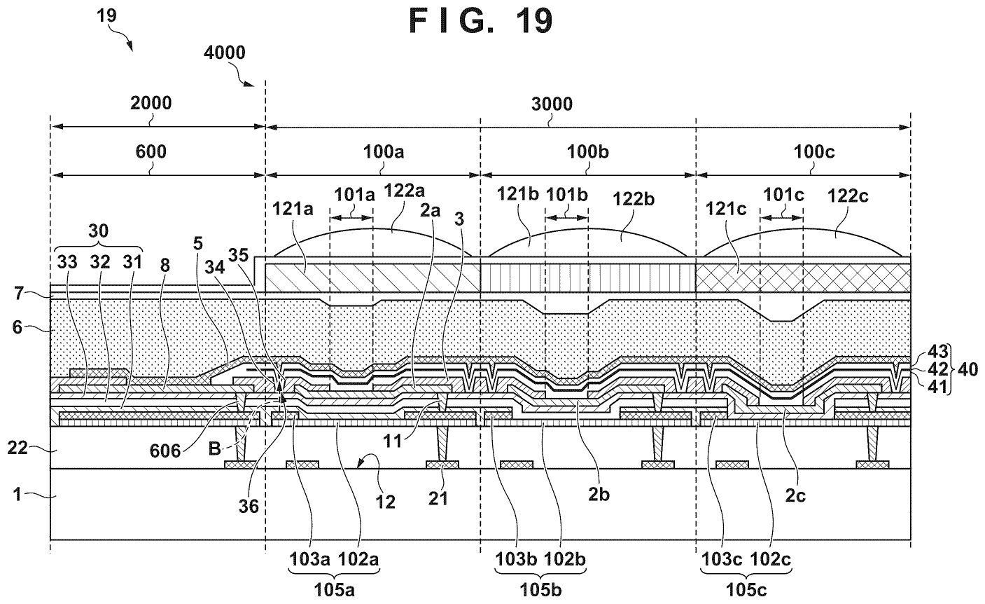

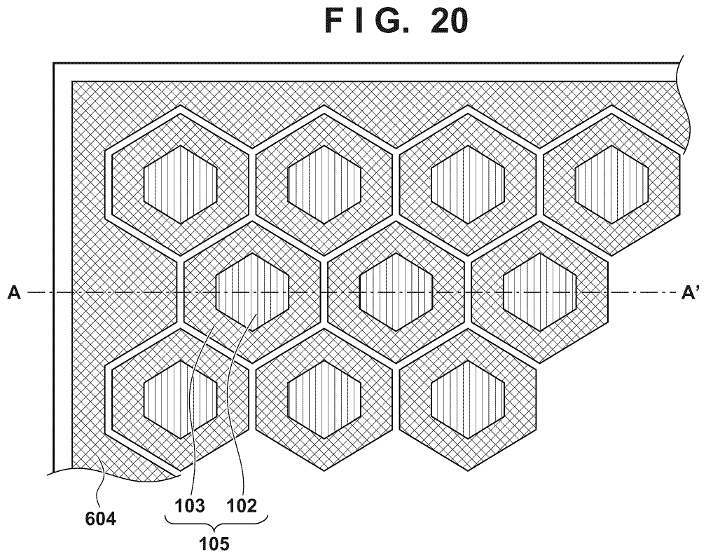

As a comparative example, a light emitting device 19 as shown in FIGS. 19 and 20 will be examined. FIG. 19 is a sectional view of the light emitting device 19 according to the comparative example, and FIG. 20 is a plan view of the light emitting device 19. FIG. 19 shows a cross section taken along a line A-A′ in FIG. 20. In the light emitting device 19, the reflective region 105 is connected to the lower electrode 2 and arranged electrically independently for each organic light emitting element 100. Also, the reflective region 105 is not electrically connected to the stacking portion 604 electrically connected to the upper electrode 5. In this case, if an electric potential difference is given between the lower electrode 2 and the upper electrode 5 to cause the organic light emitting element 100a to emit light, the electric field in the direction B is applied even to the portion of the organic layer 40 arranged on the tilting portion 34 or 35. By the electric field, in the light emitting device 19 according to the comparative example, the leakage current between the lower electrode 2 and the upper electrode 5 readily increases. On the other hand, in the light emitting device 10 according to this embodiment in which the reflective region 105 is set to an electric potential closer to the upper electrode 5 than the lower electrode 2, it is possible to suppress the leakage current between the lower electrode 2 and the upper electrode 5 while suppressing crosstalk between the organic light emitting elements 100.

The tilting portions 34 and 35 arranged on the surface of the insulating layer 3 may be arranged along the periphery of the lower electrode 2 (light emitting region 101) to surround the lower electrode 2 (light emitting region 101). The tilting portions 34 and 35 may form the side walls of the trench 36, as described above. The trench 36 may be provided to surround the plurality of lower electrodes 2 (light emitting regions 101). If tilting portions facing each other, like the tilting portions 34 and 35, exist as part of the trench 36, organic compound particles used to deposit the organic layer 40 are impeded by the insulating layer 3 having one tilting portion and are difficult to reach the other tilting portion. This can thin the charge generation layer 42. As a result, the crosstalk current between the light emitting elements 100 can be suppressed.

If the trench 36 including the tilting portions 34 and 35 is arranged, part of the charge generation layer 42 may sink in the trench 36, as shown in FIG. 17. That is, at least part of the charge generation layer 42 may be arranged on the lower side (the side of the substrate 1) of the upper end of the opening of the trench 36. This facilitates thinning of the charge generation layer 42.

The width of the upper end of the trench 36 may be wider than the thickness of a portion of the function layer 41 of the organic layer 40 in contact with the lower electrode 2. For example, the width of the upper end of the trench 36 may be wider than twice the thickness of the portion of the function layer 41 in contact with the lower electrode 2. Hence, it is difficult to seal the opening of the trench 36 by the function layer 41, and the charge generation layer 42 can readily sink in the trench 36 and thin. Also, the depth of the trench 36 may be larger than the thickness of the portion of the function layer 41 in contact with the lower electrode. The charge generation layer 42 can thus readily sink in the trench 36 and thin.

The depth of the trench 36 may be, for example, larger that the thickness of the lower electrode 2. The charge generation layer 42 can thus readily sink in the trench 36 and thin. On the other hand, the depth of the trench 36 may be smaller than the thickness of the lower electrode 2. This can prevent the organic layer 40 from thinning too much and suppress the leakage current between the lower electrode 2 and the upper electrode 5 via the organic layer 40. The depth of the trench 36 is appropriately set in accordance with the characteristics of the crosstalk current between the light emitting elements 100 and the leakage current between the lower electrode 2 and the upper electrode 5 via the organic layer 40.

In this embodiment, the lower electrode 2 has translucency, the insulating layer 30 functioning as an optical adjustment layer is provided on the lower side of the lower electrode, and the reflective layer 102 is arranged between the insulating layer 30 and the main surface 12 of the substrate 1. The thickness of the insulating layer 30 functioning as the optical adjustment layer is adjusted in accordance with a color emitted from each light emitting element 100. Hence, even if the organic layer 40 is a common layer arranged across the plurality of light emitting elements 100, the light emission efficiency of each light emitting element 100 can be increased. If the insulating layer 30 whose thickness changes in accordance with the light emission color of the light emitting element 100 is used, a tilting portion other than the tilting portions 34 and 35 can readily be arranged on the upper surface of the insulating layer 3. For this reason, even in the portion other than the tilting portions 34 and 35, the organic layer 40 is readily thinned, and the leakage current readily flows between the lower electrode 2 and the upper electrode 5 via the organic layer 40. Hence, the effect of arranging the above-described tilting portions 34 and 35 and the conductive layer is large.

The end portion of the lower electrode 2 may be arranged between the end portion of the opening portion of the electric corrosion suppression layer 103 and the end portion of the light emitting region 101. This makes it possible to reduce the field strength on the tilting portion of the insulating layer 3, which is formed by reflecting the shape of the end portion of the electric corrosion suppression layer 103. As a result, the leakage current between the lower electrode 2 and the upper electrode 5 via the organic layer 40 can be suppressed.

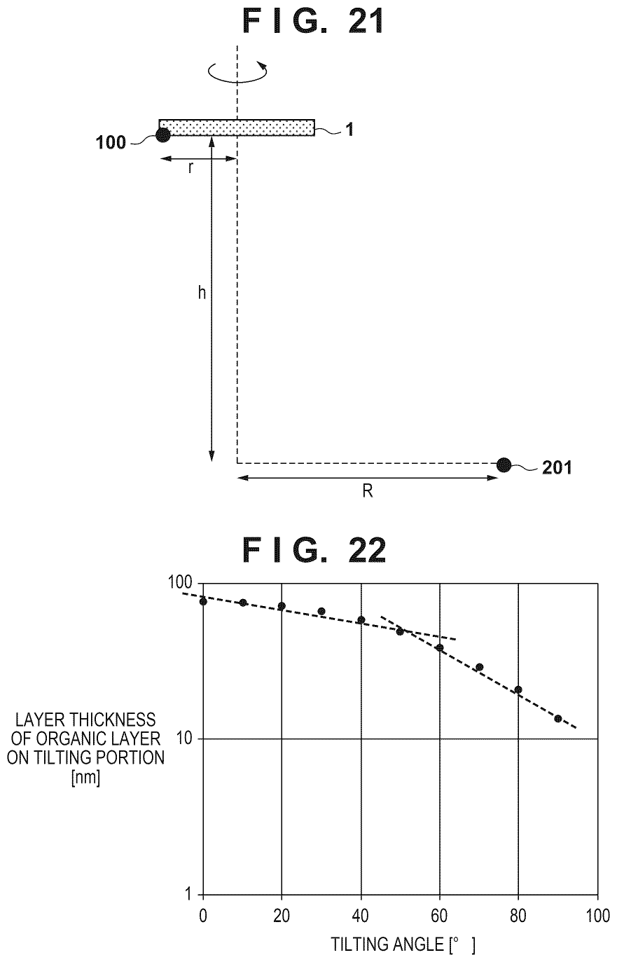

Next, a deposition simulation performed using a deposition method to obtain findings concerning the tilting angle of the tilting portions 34 and 35 will be described. FIG. 21 is a view showing the arrangement of members in the deposition simulation. The positional relationship between the deposition source 201 of the organic layer 40, the substrate 1, and the light emitting element 100 arranged on the substrate 1 were set as shown in FIG. 21. Here, R=200 mm, r=95 mm, and h=340 mm.

N indicating a deposition distribution represented by equation (3) below was set to N=2.

$$Φ = {Φ}_{0} {COS}^{N} A \qquad ( 3 )$$

Here, A is the angle of tilt in the light emitting element 100, Φ is the vapor flow density at an angle A, and Φ₀ is the vapor flow density at A=0. Also, the substrate 1 was assumed to be rotated about the center of the substrate 1 as an axis, as shown in FIG. 21.

Assuming a case where the tilting portions 34 and 35 having a tilting angle of 0° to 90° were present at the position of the light emitting element 100 on the substrate 1, the layer thickness of the organic layer 40 deposited on the tilting portions 34 and 35 at each tilting angle was calculated while defining that the layer thickness of the organic layer at a tilting angle of 0° was 76 nm.

FIG. 22 shows the result of the deposition simulation. As is apparent from the result shown in FIG. 22, if the tilting angle is 50° or more, the layer thickness of the organic layer 40 formed on the tilting portions 34 and 35 tends to be small. On the other hand, if the tilting angle is smaller than 50°, the layer thickness of the organic layer 40 formed on the tilting portions 34 and 35 tends to be large. Hence, the angle of the tilting portions 34 and 35 with respect to a virtual surface parallel to the main surface 12 of the substrate 1 may be 50° or more. The upper limit of the tilting angle is not particularly set and, for example, the tilting portions 34 and 35 may have an inverted tapered shape. For example, the angle of the tilting portions 34 and 35 with respect to the virtual surface parallel to the main surface 12 of the substrate 1 may be 50° or more and less than 180°. This makes it possible to thin the charge generation layer 42 and suppress the crosstalk current between the light emitting elements 100.

The distance between the light emitting regions 101 of the light emitting elements 100 (the pitch to arrange the light emitting elements 100) may be, for example, 10 mm or less, or may be 5 mm or less. In such a high-resolution pixel array, the crosstalk current between the light emitting elements 100 tends to be large. Hence, the effect of arranging the above-described tilting portions 34 and 35 and the conductive layer can be large.

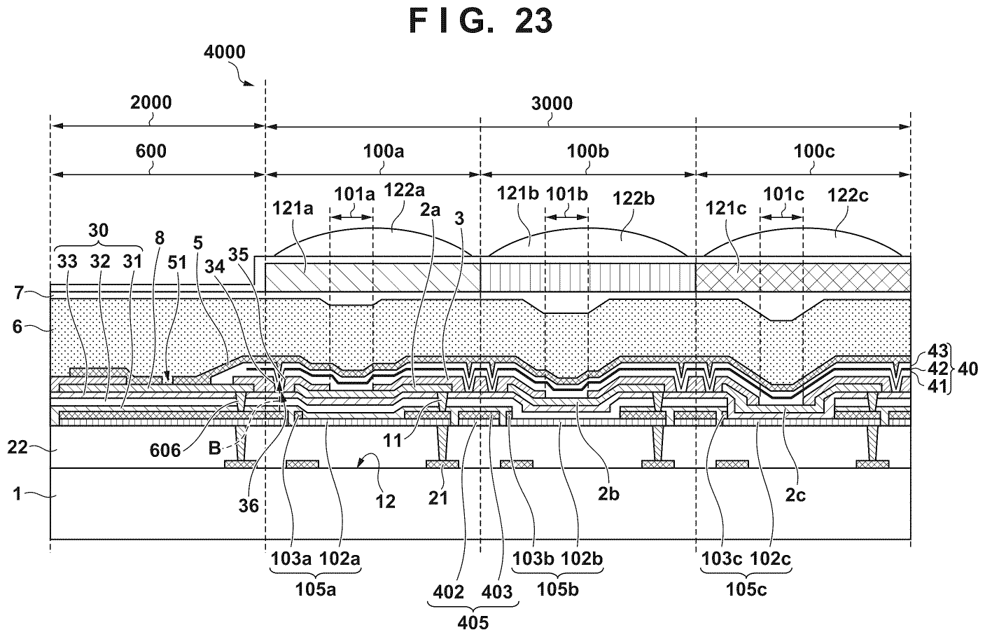

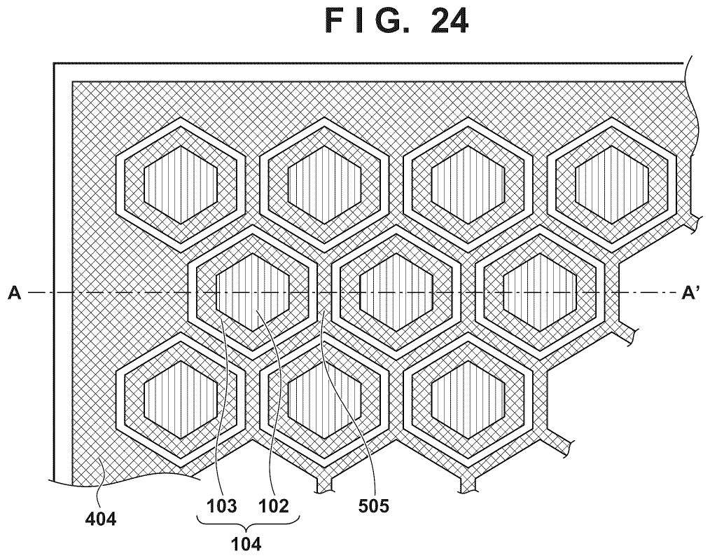

FIGS. 23 and 24 are views showing a modification of the light emitting device 10 described with reference to FIGS. 17 an 18. FIG. 23 is a sectional view showing an example of the configuration of the light emitting device 10 according to this embodiment, and FIG. 24 is a plan view showing an example of the configuration of the light emitting device 10. FIG. 23 shows a cross section taken along a line A-A′ in FIG. 24.

In this embodiment, as shown in FIGS. 23 and 24, a conductive layer 405 is arranged between the main surface 12 of the substrate 1 and the tilting portions 34 and 35 (trench 36) provided on the insulating layer 3 such that it overlaps the tilting portions 34 and 35 (trench 36) in orthogonal projection to the main surface 12 of the substrate 1. As compared to the configuration shown in FIGS. 17 and 18, the reflective region 105 and the lower electrode 2 are electrically connected via a plug (conductor 11) without arranging the pixel contact region 115. As shown in FIG. 23, the reflective region 105 is connected to a corresponding one of the plurality of lower electrodes 2 arranged in the same light emitting element 100 such that, for example, the reflective region 105a is electrically connected to the lower electrode 2a. The rest of the configuration may be the same as the configuration shown in FIGS. 17 and 18 described above, and different points will mainly be described below.

In this embodiment, as in the above-described case where the reflective region 105 is used as a conductive layer, if the lower electrode 2 serves as an anode, and the upper electrode 5 serves as a cathode, the electric potential of the conductive layer 405 is set lower than that of the lower electrode 2. Also, if the lower electrode 2 serves as a cathode, and the upper electrode 5 serves as an anode, the electric potential of the conductive layer 405 is set higher than that of the lower electrode 2. The difference between the electric potential of the conductive layer 405 and the electric potential of the upper electrode 5 may be smaller than the difference between the electric potential of the conductive layer 405 and the electric potential of the lower electrode 2. This can make the field strength applied between the upper electrode 5 and the conductive layer 405 small. For example, the difference between the electric potential of the conductive layer 405 and the electric potential of the upper electrode 5 may be 1 V or less. Furthermore, the electric potential of the conductive layer 405 and the electric potential of the upper electrode 5 may equal. In this case, the conductive layer 405 may electrically be connected to the upper electrode 5. In this embodiment, the conductive layer 405 is not electrically connected to the reflective region 105 formed by the lower electrode 2, the reflective layer 102, and the electric corrosion suppression layer 103. Also, as shown in FIG. 24, part of the stacking portion 604 may function like the conductive layer 405 that is set to an electric potential closer to the upper electrode 5 than the lower electrode 2.

In the configuration shown in FIG. 24, the layer thickness of the insulating layer 30 arranged between the lower electrode 2c and a reflective region 105c of the organic light emitting element 100c is thinner than the layer thickness of the insulating layer 30 arranged between the lower electrodes 2a and 2b and reflective regions 105a and 105b of the organic light emitting elements 100a and 100b. For this reason, due to the electric potential difference between the lower electrode 2c and the reflective region 105c, the insulating layer 30 arranged between the lower electrode 2c and the reflective region 105c causes dielectric breakdown at higher possibility than the remaining portions. In this embodiment, since the lower electrode 2c has the same electric potential as the reflective region 105c, dielectric breakdown of the insulating layer 30 (insulating layer 33) between the lower electrode 2c and the reflective region 105c is suppressed.

Also, in this embodiment as well, the conductive layer 405 arranged to overlap the tilting portions 34 and 35 (trench 36) in orthogonal projection to the main surface 12 of the substrate 1 is set to an electric potential approximate to the upper electrode 5 or the same electric potential as the upper electrode 5. For this reason, the field strength in the direction B, which is applied to the portion of the organic layer 40 arranged on the tilting portions 34 and 35 can be suppressed. Hence, as described above, it is possible to suppress the leakage current between the lower electrode 2 and the upper electrode 5 via the organic layer 40 while suppressing crosstalk between the light emitting elements 100.

The conductive layer 405 can be formed at the same time as the formation of the reflective region 105. When the conductive layer 405 and the reflective region 105 are created by the same process, an increase in the number of steps of manufacturing the light emitting device 10 can be suppressed. If the conductive layer 405 is formed at the same time as the reflective region 105, the conductive layer 405 includes, between the interlayer insulating layer 22 and the insulating layer 30, a reflective layer 402 whose main component is the same as the reflective layer 102, and between the reflective layer 402 and the insulating layer 30, an electric corrosion suppression layer 403 whose main component is the same as the electric corrosion suppression layer 103. Hence, the height of the lower surface of the reflective region 105 and that of the lower surface of the conductive layer 405 from the main surface 12 of the substrate 1 may equal. Also, for example, the height of the upper surface of the reflective region 105 and that of the upper surface of the conductive layer 405 from the main surface 12 of the substrate 1 may equal. That is, the conductive layer 405 and the reflective region 105 may be arranged at the same height from the main surface 12 of the substrate 1.

In the configurations shown in FIGS. 17, 18, 23, and 24, the contact portion 51 (supply electrode 8) of the upper electrode 5 is not provided in the display region 3000. However, the present invention is not limited to this, and in addition to the configurations shown in FIGS. 17, 18, 23, and 24, the contact portion 51 (supply electrode 8) may be arranged in the display region 3000, like the configurations shown in FIGS. 2 to 8. The above-described embodiments may appropriately be used in combination.

Application examples in which the light emitting device 10 according to this embodiment is applied to a display device, a photoelectric conversion device, an electronic apparatus, an illumination device, a moving body, and a wearable device will be described here with reference to FIGS. 25 to 31A and 31B.

FIG. 25 is a schematic view showing an example of the display device using the light emitting device 10 of this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting device 10 can be applied to the display panel 1005. The display region 3000 of the light emitting device 10 functioning as the display panel 1005 is connected to the active elements such as transistors arranged on the circuit board 1007 and operates.

The display device 1000 shown in FIG. 25 can be used for a display unit of a photoelectric conversion device (image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

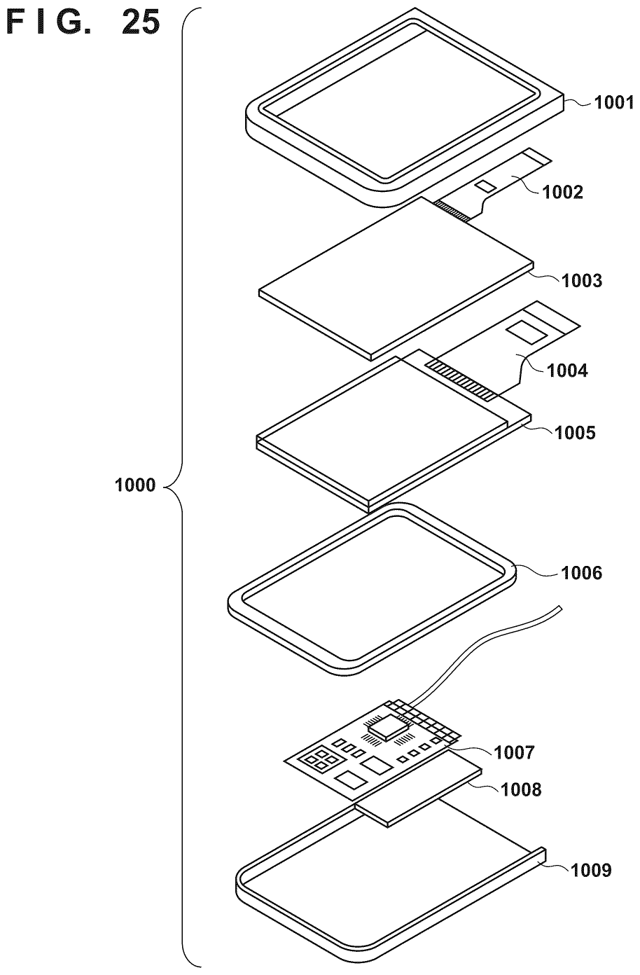

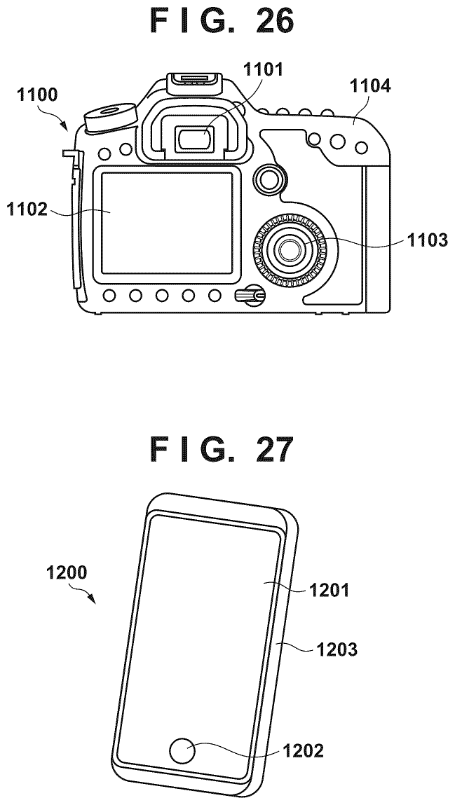

FIG. 26 is a schematic view showing an example of the photoelectric conversion device using the light emitting device 10 of this embodiment. A photoelectric conversion device 1100 can include a viewfinder 1101, a rear display 1102, an operation unit 1103, and a housing 1104. The photoelectric conversion device 1100 can also be called an image capturing device. The light emitting device 10 according to this embodiment can be applied to the viewfinder 1101 or the rear display 1102 as a display unit. In this case, the display region 3000 of the light emitting device 10 can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, so the information should be displayed as soon as possible. Therefore, the light emitting device 10 in which the organic light emitting element 100 using the organic light emitting material such as an organic EL element is arranged in the display region 3000 may be used for the viewfinder 1101 or the rear display 1102. This is so because the organic light emitting material has a high response speed. The light emitting device 10 using the organic light emitting material can be used for the apparatuses that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 10 may be applied to a display unit of an electronic apparatus. At this time, the display unit can have both a display function and an operation function. Examples of the portable terminal are a portable phone such as a smartphone, a tablet, and a head mounted display.

FIG. 27 is a schematic view showing an example of an electronic apparatus using the light emitting device 10 of this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 10 according to this embodiment can be applied to the display unit 1201.

FIGS. 28A and 28B are schematic views showing examples of the display device using the light emitting device 10 of this embodiment. FIG. 28A shows a display device such as a television monitor or a PC monitor. A display device 1300 includes a frame 1301 and a display unit 1302. The light emitting device 10 according to this embodiment can be applied to the display unit 1302. The display device 1300 can include a base 1303 that supports the frame 1301 and the display unit 1302. The base 1303 is not limited to the form shown in FIG. 28A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 28B is a schematic view showing another example of the display device using the light emitting device 10 of this embodiment. A display device 1310 shown in FIG. 28B can be folded, and is a so-called foldable display device. The display device 1310 includes a first display unit 1311, a second display unit 1312, a housing 1313, and a bending point 1314. The light emitting device 10 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

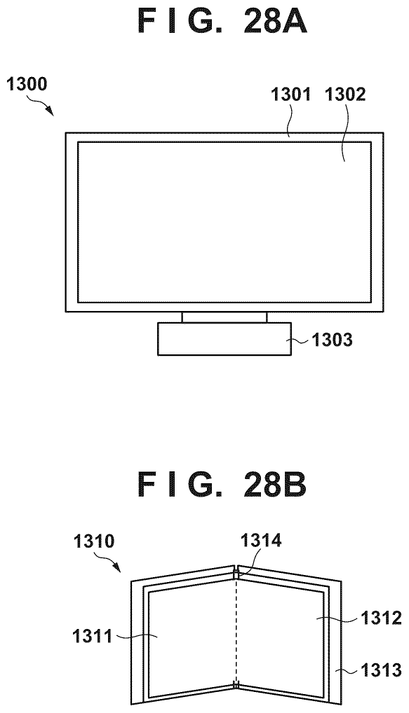

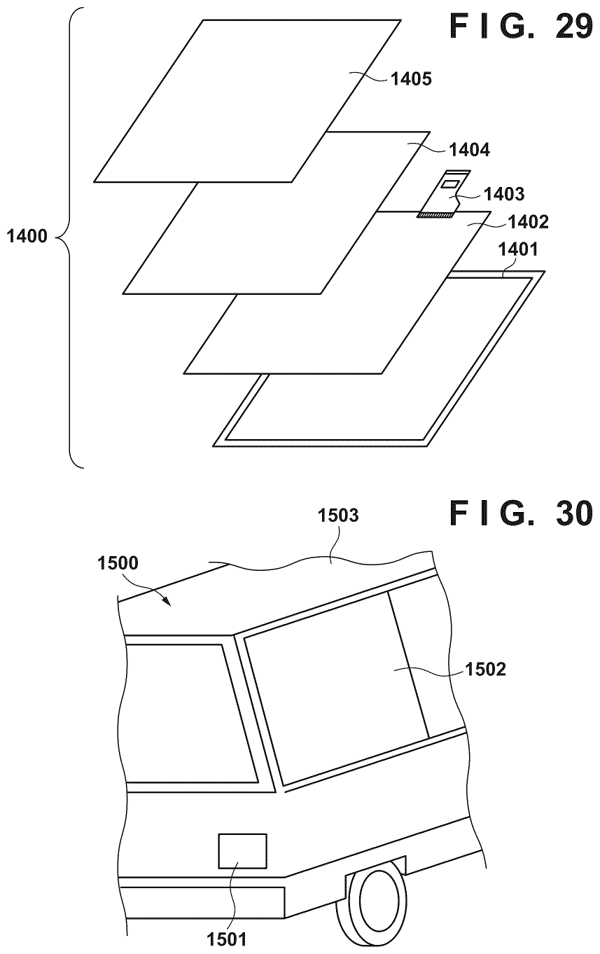

FIG. 29 is a schematic view showing an example of the illumination device using the light emitting device 10 of this embodiment. An illumination device 1400 can include a housing 1401, a light source 1402, a circuit board 1403, an optical film 1404, and a light diffusing unit 1405. The light emitting device 10 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the display region 3000 of the light emitting device 10 functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicon.

FIG. 30 is a schematic view of an automobile having a taillight as an example of a vehicle lighting appliance using the light emitting device 10 of this embodiment. An automobile 1500 has a taillight 1501, and can have a form in which the taillight 1501 is turned on when performing a braking operation or the like. The light emitting device 10 of this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device 10 according to this embodiment can be applied to the taillight 1501. The taillight 1501 can include a protection member for protecting the display region 3000 of the light emitting device 10 functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display. For this transparent display, the light emitting device 10 according to this embodiment may be used. In this case, the constituent materials of the electrodes and the like of the light emitting device 10 are formed by transparent members.

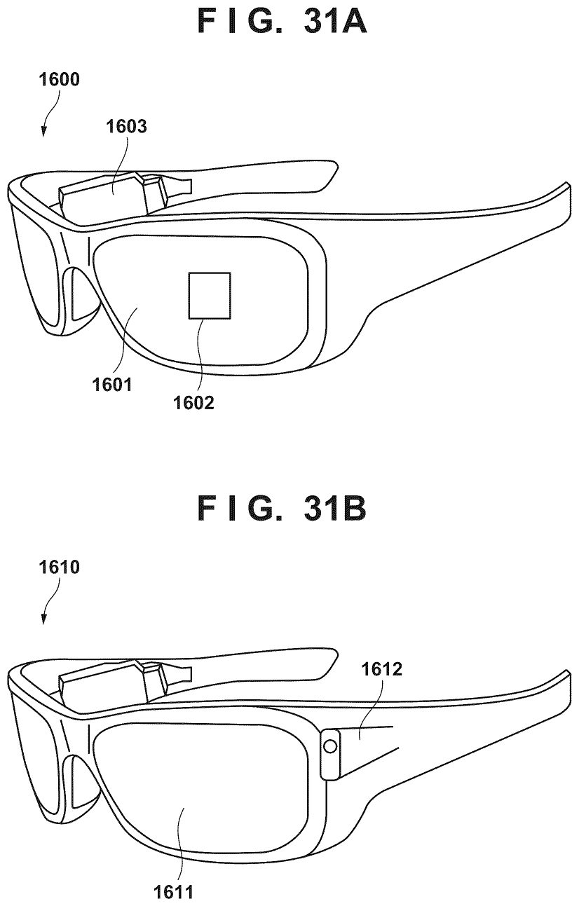

Further application examples of the light emitting device 10 according to this embodiment will be described with reference to FIGS. 31A and 31B. The light emitting device 10 can be applied to a system that can be worn as a wearable device such as smartglasses, an HMD (Head Mounted Display), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 31A. An image capturing device 1602 such as a CMOS sensor or an SPAD is provided on the surface side of a lens 1601 of the glasses 1600. In addition, the light emitting device 10 according to this embodiment is provided on the back surface side of the lens 1601.

The glasses 1600 further include a control device 1603. The control device 1603 functions as a power supply that supplies electric power to the image capturing device 1602 and the light emitting device 10 according to each embodiment. In addition, the control device 1603 controls the operations of the image capturing device 1602 and the light emitting devices 10 to 70. An optical system configured to condense light to the image capturing device 1602 is formed on the lens 1601.

Glasses 1610 (smartglasses) according to one application example will be described with reference to FIG. 31B. The glasses 1610 include a control device 1612, and an image capturing device corresponding to the image capturing device 1602 and the light emitting device 10 are mounted on the control device 1612. The image capturing device in the control device 1612 and an optical system configured to project light emitted from the light emitting device 10 are formed in a lens 1611, and an image is projected to the lens 1611. The control device 1612 functions as a power supply that supplies electric power to the image capturing device and the light emitting device 10, and controls the operations of the image capturing device and the light emitting device 10. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 10 according to the embodiment of the present disclosure can include an image capturing device including a light receiving element, and control a displayed image based on the line-of-sight information of the user from the image capturing device.

More specifically, the light emitting device 10 decides a first visual field region at which the user is gazing and a second visual field region other than the first visual field region based on the line-of-sight information. The first visual field region and the second visual field region may be decided by the control device of the light emitting device 10, or those decided by an external control device may be received. In the display region of the light emitting device 10, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 10, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 10, the image capturing device, or an external device. If the external device holds the AI program, it is transmitted to the light emitting device 10 via communication.

When performing display control based on line-of-sight detection, smartglasses further including an image capturing device configured to capture the outside can be applied. The smartglasses can display captured outside information in real time.

According to the present invention, it is possible to provide a technique advantageous in suppressing lowering of the display quality of a light emitting device.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A light emitting device comprising: an insulating layer arranged on a main surface of a substrate, a plurality of lower electrodes arranged on the insulating layer, an organic layer arranged to cover the plurality of lower electrodes, an upper electrode arranged to cover the organic layer, and a supply electrode configured to supply an electric potential to the upper electrode, wherein
the organic layer includes a plurality of function layers each including a light emitting layer, and a charge generation layer arranged between the plurality of function layers,
the upper electrode includes a contact portion that is in contact with the supply electrode,
in orthogonal projection to the main surface, the insulating layer includes a trench between the contact portion and each of the plurality of lower electrodes, and
a thickness of the charge generation layer in the trench is thinner than the thickness of the charge generation layer on the plurality of lower electrodes.

2. The light emitting device according to claim 1, wherein
the plurality of lower electrodes include a first lower electrode and a second lower electrode, which are adjacent to each other, and
in orthogonal projection to the main surface, the contact portion is arranged between the first lower electrode and the second lower electrode and at least partially surrounded by the trench.

3. The light emitting device according to claim 2, wherein
the plurality of lower electrodes further include a third lower electrode and a fourth lower electrode, which are adjacent to each other,
in orthogonal projection to the main surface, the contact portion is not arranged between the third lower electrode and the fourth lower electrode, and
a center distance between the first lower electrode and the second lower electrode equals a center distance between the third lower electrode and the fourth lower electrode.

4. The light emitting device according to claim 2, wherein
the plurality of lower electrodes further include a third lower electrode and a fourth lower electrode, which are adjacent to each other,
in orthogonal projection to the main surface, the contact portion is not arranged between the third lower electrode and the fourth lower electrode, and
a center distance between the first lower electrode and the second lower electrode is longer than a center distance between the third lower electrode and the fourth lower electrode.

5. The light emitting device according to claim 4, wherein
the center distance between the first lower electrode and the second lower electrode is twice the center distance between the third lower electrode and the fourth lower electrode.

6. The light emitting device according to claim 1, wherein
in orthogonal projection to the main surface, each of portions of the organic layer in contact with the plurality of lower electrodes is at least partially surrounded by the trench.

7. The light emitting device according to claim 6, wherein
the plurality of lower electrodes include a first lower electrode and a second lower electrode, which are adjacent to each other, and
in orthogonal projection to the main surface, the contact portion is arranged between the first lower electrode and the second lower electrode.

8. The light emitting device according to claim 6, wherein
in orthogonal projection to the main surface,
the organic layer and the upper electrode are arranged up to an outer peripheral region outside a display region in which the plurality of lower electrodes are arranged, and
the contact portion is arranged in a region of the outer peripheral region, in which the organic layer is arranged.

9. The light emitting device according to claim 6, wherein
in orthogonal projection to the main surface,
the organic layer and the upper electrode are arranged up to an outer peripheral region outside a display region in which the plurality of lower electrodes are arranged,
the upper electrode is arranged up to an outside of the organic layer in the outer peripheral region, and
the contact portion is arranged in a region of the outer peripheral region outside the organic layer.

10. The light emitting device according to claim 1, wherein
the upper electrode and the charge generation layer are electrically connected.

11. The light emitting device according to claim 1, wherein
in orthogonal projection to the main surface,
the organic layer and the upper electrode are arranged up to an outer peripheral region outside a display region in which the plurality of lower electrodes are arranged, and
the contact portion is arranged in a region of the outer peripheral region, in which the organic layer is arranged, and at least partially surrounded by the trench.

12. The light emitting device according to claim 1, wherein
in orthogonal projection to the main surface,
the organic layer and the upper electrode are arranged up to an outer peripheral region outside a display region in which the plurality of lower electrodes are arranged,
the contact portion is arranged in a region of the outer peripheral region, in which the organic layer is arranged, and
the display region is at least partially surrounded by the trench.

13. The light emitting device according to claim 1, wherein
in orthogonal projection to the main surface,
the organic layer and the upper electrode are arranged up to an outer peripheral region outside a display region in which the plurality of lower electrodes are arranged,
the upper electrode is arranged up to an outside of the organic layer in the outer peripheral region,
the contact portion is arranged in a region of the outer peripheral region outside the organic layer, and
the display region is at least partially surrounded by the trench.

14. The light emitting device according to claim 13, wherein
in the outer peripheral region, the upper electrode and the charge generation layer are electrically connected.

15. The light emitting device according to claim 1, wherein
the plurality of function layers include a first function layer that is in contact with the plurality of lower electrodes, and
a distance between upper sides facing each other in the trench is not less than twice a thickness of a portion of the first function layer in contact with the plurality of lower electrodes.

16. The light emitting device according to claim 1, wherein
a length between upper sides facing each other in the trench is shorter than a depth of the trench.

17. The light emitting device according to claim 1, wherein
a portion of the charge generation layer sunk in the trench includes a portion having a film thickness of not more than ½ a portion of the charge generation layer arranged on the plurality of lower electrodes.

18. The light emitting device according to claim 1, wherein
the portion of the charge generation layer sunk in the trench includes a discontinuous portion.

19. The light emitting device according to claim 1, wherein
the upper electrode is not sunk in the trench.

20. The light emitting device according to claim 1, wherein
the upper electrode is continuously arranged on the trench.

21. A light emitting device comprising: an insulating layer arranged on a main surface of a substrate, a plurality of lower electrodes arranged on the insulating layer, an organic layer arranged to cover the plurality of lower electrodes, an upper electrode arranged to cover the organic layer, and a supply electrode configured to supply an electric potential to the upper electrode, wherein
the organic layer includes a plurality of function layers each including a light emitting layer, and a charge generation layer arranged between the plurality of function layers,
the upper electrode includes a contact portion that is in contact with the supply electrode, and
an electric field application electrode configured to apply an electric field to the charge generation layer is arranged between the insulating layer and the organic layer and, in orthogonal projection to the main surface, between the contact portion and each of the plurality of lower electrodes.

22. The light emitting device according to claim 21, wherein
during an operation of the light emitting device, a voltage not less than a light emission threshold of the light emitting layer is applied between the electric field application electrode and the upper electrode.

23. A light emitting device comprising: a first insulating layer arranged on a main surface of a substrate, a plurality of lower electrodes arranged on the first insulating layer, a second insulating layer arranged on the first insulating layer and between the plurality of lower electrodes, an organic layer arranged to cover the plurality of lower electrodes and the second insulating layer, an upper electrode arranged to cover the organic layer, and a supply electrode configured to supply an electric potential to the upper electrode, wherein
the organic layer includes a plurality of function layers each including a light emitting layer, and a charge generation layer arranged between the plurality of function layers,
the upper electrode includes a contact portion that is in contact with the supply electrode,
on a surface of the second insulating layer facing the organic layer, a tilting portion having a tilt with respect to the main surface is arranged between the contact portion and each of the plurality of lower electrodes in orthogonal projection to the main surface,
a conductive layer is further arranged between the main surface and the tilting portion to overlap the tilting portion in orthogonal projection to the main surface, and
an electric potential of the conductive layer is
lower than that of the plurality of lower electrodes in a case where the plurality of lower electrodes serve as an anode and the upper electrode serves as a cathode, and
higher than that of the plurality of lower electrodes in a case where the plurality of lower electrodes serve as a cathode and the upper electrode serves as an anode.

24. The light emitting device according to claim 23, wherein
a difference between the electric potential of the conductive layer and an electric potential of the upper electrode is smaller than a difference between the electric potential of the conductive layer and an electric potential of the plurality of lower electrodes.

25. The light emitting device according to claim 23, wherein
the electric potential of the conductive layer equals the electric potential of the upper electrode.

26. The light emitting device according to claim 23, wherein
the conductive layer is electrically connected to the upper electrode.

27. The light emitting device according to claim 23, wherein
in the surface of the second insulating layer, a trench is provided to surround each of the plurality of lower electrodes, and
the tilting portion forms a side wall of the trench.

28. The light emitting device according to claim 23, wherein
an angle of the tilting portion with respect to a virtual surface parallel to the main surface is not less than 50°.

29. The light emitting device according to claim 23, wherein
the plurality of lower electrodes have translucency,
a reflective region including a reflective layer in correspondence with each of the plurality of lower electrodes is arranged between the main surface and the first insulating layer, and
the reflective region functions as the conductive layer.

30. The light emitting device according to claim 23, wherein
the plurality of lower electrodes have translucency,
a reflective region including a reflective layer in correspondence with each of the plurality of lower electrodes is arranged between the main surface and the first insulating layer,
the reflective region is electrically connected to a corresponding one of the plurality of lower electrodes, and
the conductive layer is not electrically connected to the reflective region.

31. The light emitting device according to claim 30, wherein
the conductive layer and the reflective region are arranged at the same height from the main surface.

32. The light emitting device according to claim 23, wherein
the conductive layer is not electrically connected to the plurality of lower electrodes.

33. A display device comprising the light emitting device according to claim 1, and an active element connected to the light emitting device.

34. A photoelectric conversion device comprising an optical unit including a plurality of lenses, an image sensor configured to receive light having passed through the optical unit, and a display unit configured to display an image,
wherein the display unit displays an image captured by the image sensor, and includes the light emitting device according to claim 1.

35. An electronic apparatus comprising a housing provided with a display unit, and a communication unit provided in the housing and configured to perform external communication,
wherein the display unit includes the light emitting device according to claim 1.

36. An illumination device comprising a light source, and at least one of a light diffusing unit and an optical film,
wherein the light source includes the light emitting device according to claim 1.

37. A moving body comprising a main body, and a lighting appliance provided in the main body,
wherein the lighting appliance includes the light emitting device according to claim 1.
